(19) United States
(12) Patent Application Publication
(10) Pub. No.: US 2022/0020681 A1
(43) Pub. Date: Jan. 20, 2022

(54) SEMICONDUCTOR MEMORY DEVICE

(71) Applicant: Kioxia Corporation, Tokyo (JP)

(72) Inventors: Kazuhiro NOJIMA, Mie (JP); Genki KAWAGUCHI, Yokkaichi (JP)

(73) Assignee: Kioxia Corporation, Tokyo (JP)

(21) Appl. No.: 17/145,521

(22) Filed: Jan. 11, 2021

(30) Foreign Application Priority Data
Jul. 20, 2020 (JP) 2020-123677

(51) Int. Cl. H01L 23/528; H01L 27/11582; H01L 27/1157

(52) U.S. Cl. CPC H01L 23/528; H01L 27/1157; H01L 27/11582

(57) ABSTRACT

A semiconductor memory device according to an embodiment includes a substrate. The substrate includes first and second areas, and block areas. The second area includes subareas. Each of the subareas includes a contact area and an insulating area arranged in the first direction. The contact area includes terraced portions and first contacts corresponding to two block areas. The insulating area includes second contacts corresponding to the two block areas. Contact areas of odd-numbered subareas and insulating areas of even-numbered subareas are disposed in an alternating manner in the second direction. Insulating areas of the odd-numbered subareas and contact areas of the even-numbered subareas are disposed in an alternating manner in the second direction.

### CROSS-REFERENCE TO RELATED APPLICATIONS

This application is based upon and claims the benefit of priority from Japanese Patent Application No. 2020-123677, filed Jul. 20, 2020, the entire contents of which are incorporated herein by reference.

### FIELD

Embodiments described herein relate generally to a semiconductor memory device.

### BACKGROUND

A NAND flash memory capable of storing data in a nonvolatile manner is known.

### BRIEF DESCRIPTION OF THE DRAWINGS

FIG. 1 is a block diagram showing an example of an overall configuration of a semiconductor memory device according to a first embodiment.

FIG. 2 is a circuit diagram showing an example of a circuit configuration of a memory cell array included in the semiconductor memory device according to the first embodiment.

FIG. 3 is a circuit diagram showing an example of a circuit configuration of a row decoder module included in the semiconductor memory device according to the first embodiment.

FIG. 4 is a plan view showing an example of a planar layout of the memory cell array included in the semiconductor memory device according to the first embodiment.

FIG. 5 is a plan view showing an example of a detailed planar layout in a memory area of the memory cell array included in the semiconductor memory device according to the first embodiment.

FIG. 6 is a cross-sectional view, taken along line VI-VI in FIG. 5, showing an example of a cross-sectional structure in the memory area of the memory cell array included in the semiconductor memory device according to the first embodiment.

FIG. 7 is a cross-sectional view, taken along line VII-VII in FIG. 6, showing an example of a planar structure of a memory pillar in the semiconductor memory device according to the first embodiment.

FIG. 8 is a plan view showing an example of a detailed planar layout in a hookup area of the memory cell array included in the semiconductor memory device according to the first embodiment.

FIG. 9 is a plan view showing an example of a detailed planar layout in the hookup area of the memory cell array included in the semiconductor memory device according to the first embodiment.

FIG. 10 is a cross-sectional view, taken along line X-X in FIG. 9, showing an example of a cross-sectional structure in the hookup area of the memory cell array included in the semiconductor memory device according to the first embodiment.

FIG. 11 is a cross-sectional view, taken along line XI-XI in FIG. 9, showing an example of a cross-sectional structure in the hookup area of the memory cell array included in the semiconductor memory device according to the first embodiment.

FIG. 12 is a plan view showing an example of a planar layout of a memory cell array in a comparative example of the first embodiment.

FIG. 13 is a cross-sectional view showing an example of a cross-sectional structure of the memory cell array in the comparative example of the first embodiment.

FIG. 14 is a plan view showing an example of a planar layout in a hookup area of a memory cell array included in a semiconductor memory device according to a second embodiment.

FIG. 15 is a plan view showing an example of a detailed planar layout in the hookup area of the memory cell array included in the semiconductor memory device according to the second embodiment.

FIG. 16 is a plan view showing an example of a detailed planar layout in the hookup area of the memory cell array included in the semiconductor memory device according to the second embodiment.

FIG. 17 is a cross-sectional view, taken along line XVII-XVII in FIG. 16, showing an example of a cross-sectional structure in the hookup area of the memory cell array included in the semiconductor memory device according to the second embodiment.

FIG. 18 is a cross-sectional view, taken along line XVIII-XVIII in FIG. 16, showing an example of a cross-sectional structure in the hookup area of the memory cell array included in the semiconductor memory device according to the second embodiment.

FIG. 19 is a plan view showing an example of a detailed planar layout in a hookup area of a memory cell array included in a semiconductor memory device according to a third embodiment.

FIG. 20 is a plan view showing an example of a detailed planar layout in the hookup area of the memory cell array included in the semiconductor memory device according to the third embodiment.

FIG. 21 is a cross-sectional view, taken along line XXI-XXI in FIG. 20, showing an example of a cross-sectional structure in the hookup area of the memory cell array included in the semiconductor memory device according to the third embodiment.

FIG. 22 is a cross-sectional view, taken along line XXII-XXII in FIG. 20, showing an example of a cross-sectional structure in the hookup area of the memory cell array included in the semiconductor memory device according to the third embodiment.

FIG. 23 is a plan view showing an example of a detailed planar layout in a hookup area of a memory cell array included in a semiconductor memory device according to a fourth embodiment.

FIG. 24 is a cross-sectional view, taken along line XXIV-XXIV in FIG. 23, showing an example of a cross-sectional structure in the hookup area of the memory cell array included in the semiconductor memory device according to the fourth embodiment.

FIG. 25 is a plan view showing a development process of replacement processing in a comparative example of the fourth embodiment.

FIG. 26 is a plan view showing a development process of replacement processing in the fourth embodiment.

FIG. 27 is a plan view showing an example of a detailed planar layout in a hookup area of a memory cell array included in a semiconductor memory device according to a modification of the fourth embodiment.

FIG. 28 is a plan view showing an example of a planar layout in a hookup area of a memory cell array included in a semiconductor memory device according to a fifth embodiment.

FIG. 29 is a cross-sectional view, taken along line XXIX-XXIX in FIG. 28, showing an example of a cross-sectional structure in the hookup area of the memory cell array included in the semiconductor memory device according to the fifth embodiment.

FIG. 30 is a cross-sectional view showing a development process of replacement processing in a comparative example of the fifth embodiment.

FIG. 31 is a cross-sectional view showing a development process of replacement processing in the fifth embodiment.

FIG. 32 is a plan view showing an example of a detailed planar layout in a hookup area of a memory cell array included in a semiconductor memory device according to a first modification of the fifth embodiment.

FIG. 33 is a plan view showing an example of a detailed planar layout in a hookup area of a memory cell array included in a semiconductor memory device according to a second modification of the fifth embodiment.

FIG. 34 is a plan view showing an example of a detailed planar layout in a hookup area of a memory cell array included in a semiconductor memory device according to a third modification of the fifth embodiment.

FIG. 35 is a plan view showing an example of a detailed planar layout in a hookup area of a memory cell array included in a semiconductor memory device according to a fourth modification of the fifth embodiment.

FIG. 36 is a plan view showing an example of a detailed planar layout in a hookup area of a memory cell array included in a semiconductor memory device according to a sixth embodiment.

FIG. 37 is a cross-sectional view, taken along line XXXVII-XXXVII in FIG. 36, showing an example of a cross-sectional structure in the hookup area of the memory cell array included in the semiconductor memory device according to the sixth embodiment.

FIG. 38, FIG. 39, FIG. 40, FIG. 41 and FIG. 42 are cross-sectional views showing an example of a processing method of a stepped structure in the hookup area of the memory cell array included in the semiconductor memory device according to the sixth embodiment.

FIG. 43 is a plan view showing an example of a detailed planar layout in a hookup area of a memory cell array included in a semiconductor memory device according to a modification of the sixth embodiment.

### DETAILED DESCRIPTION

In general, according to one embodiment, a semiconductor memory device includes a substrate, a plurality of insulating members, a plurality of first conductive layers, a plurality of first pillars, a plurality of first contacts, a plurality of second conductive layers, and a plurality of second contacts. The substrate includes a first area, a second area, and a plurality of block areas. The first area and the second area are arranged in a first direction. Each of the block areas is provided to extend in the first direction. The block areas are arranged in a second direction intersecting the first direction. The insulating members are provided to extend in the first direction. The insulating members are respectively disposed at boundary portions between the block areas. The first conductive layers are arranged in a third direction intersecting the first and second directions and provided to be separated from one another. The first conductive layers are divided by the insulating members. The first conductive layers respectively include terraced portions provided not to overlap an upper first conductive layer for each area in which the second area and any one of the block areas overlap. The first pillars are provided to penetrate the first conductive layers for each area in which the first area and any one of the block areas overlap. The first contacts are respectively provided on the terraced portions of the first conductive layers for each of the block areas. The second conductive layers are respectively coupled to the first contacts above the first conductive layers for each of the block areas. The second contacts are provided to extend from a first layer to a second layer and respectively coupled to the second conductive layers for each of the block areas. The first layer is located above the first conductive layers. The second layer is located between the substrate and the first conductive layers. The second area includes a plurality of subareas arranged in the second direction. Each of the subareas is disposed across a boundary between two different block areas to overlap a part of each of the two different block areas in the second direction. Each of the subareas includes a contact area and an insulating area arranged in the first direction. The contact area includes a group of the terraced portions and a group of the first contacts corresponding to two block areas. The insulating area includes a group of the second contacts corresponding to the two block areas. Contact areas of odd-numbered subareas and insulating areas of even-numbered subareas are disposed in an alternating manner in the second direction. Insulating areas of the odd-numbered subareas and contact areas of the even-numbered subareas are disposed in an alternating manner in the second direction.

Embodiments will be described below with reference to the accompanying drawings. Each embodiment exemplifies a device and a method for embodying a technical idea of an invention. The drawings are schematic or conceptual, and it is not a requisite that the dimensions, scale, etc., read from each drawing conform to actual products. The technical idea of the present invention is not specified by the shapes, structures, arrangements, etc. of the structural elements.

In the following descriptions, structural elements having substantially the same function and configuration will be assigned the same reference symbol. The numbers after the letters constituting the reference symbols are used to discriminate elements denoted by the reference symbols including the same letters and which have similar configurations. Where there is no need to distinguish between such elements, they are referred to by the reference symbol with the letter only.

### [1] First Embodiment

Hereinafter, a semiconductor memory device 1 according to a first embodiment will be described.

### [1-1] Overall Configuration of Semiconductor Memory Device 1

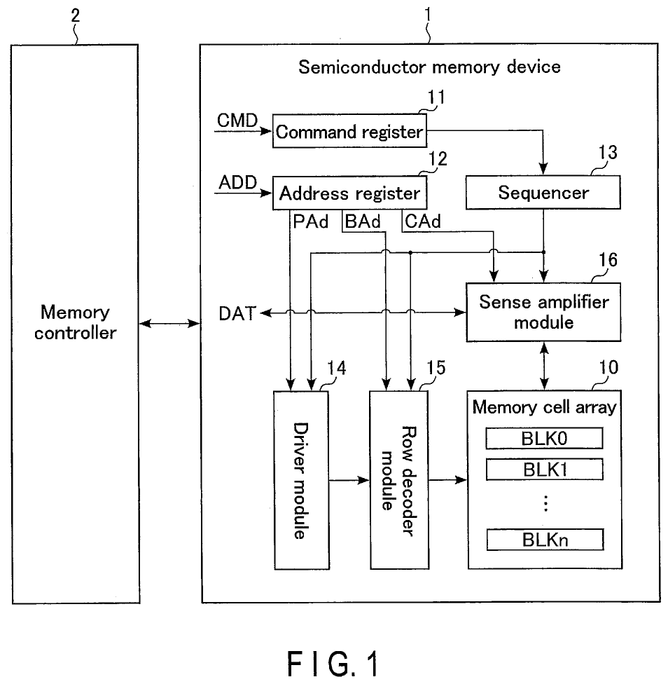

FIG. 1 shows a configuration example of the semiconductor memory device 1 according to the first embodiment. The semiconductor memory device 1 is a NAND flash memory capable of storing data in a nonvolatile manner, and is controllable by an external memory controller 2.

As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer of 1 or more). A block BLK is a set of a plurality of memory cells capable of storing data in a nonvolatile manner, and is, for example, used as a data erase unit. A plurality of bit lines and word lines are provided in the memory cell array 10. Each memory cell is, for example, associated with one bit line and one word line. A detailed configuration of the memory cell array 10 will be described later.

The command register 11 holds a command CMD received by the semiconductor memory device 1 from the memory controller 2. The command CMD includes, for example, a command for causing the sequencer 13 to execute a read operation, a write operation, an erase operation, etc.

The address register 12 holds address information ADD received by the semiconductor memory device 1 from the memory controller 2. The address information ADD includes, for example, a block address BAd, a page address PAd, and a column address CAd. For example, the block address BAd, page address PAd, and column address CAd are used for selection of a block BLK, a word line, and a bit line, respectively.

The sequencer 13 controls the overall operation of the semiconductor memory device 1. For example, the sequencer 13 controls the driver module 14, row decoder module 15, and sense amplifier module 16, etc., based on a command CMD held in the command register 11, to execute the read, write, and erase operations, etc.

The driver module 14 generates a voltage to be used for the read, write, and erase operations, etc. The driver module 14 applies the generated voltage to a signal line corresponding to a selected word line, for example, based on a page address PAd held in the address register 12.

The row decoder module 15 selects one corresponding block BLK in the memory cell array 10, based on a block address BAd held in the address register 12. The row decoder module 15, for example, transfers the voltage applied to the signal line corresponding to the selected word line to the selected word line in the selected block BLK.

The sense amplifier module 16 applies a desired voltage to each bit line in a write operation, in accordance with write data DAT received from the memory controller 2. In a read operation, the sense amplifier module 16 determines data stored in a memory cell based on the voltage of the bit line, and transfers the determination result to the memory controller 2 as read data DAT.

The above-described semiconductor memory device 1 and memory controller 2 may be combined into a single semiconductor device. Examples of such semiconductor devices include a memory card such as an SD™ card, and a solid state drive (SSD).

### [1-2] Circuit Configuration of Semiconductor Memory Device 1

### [1-2-1] Circuit Configuration of Memory Cell Array 10

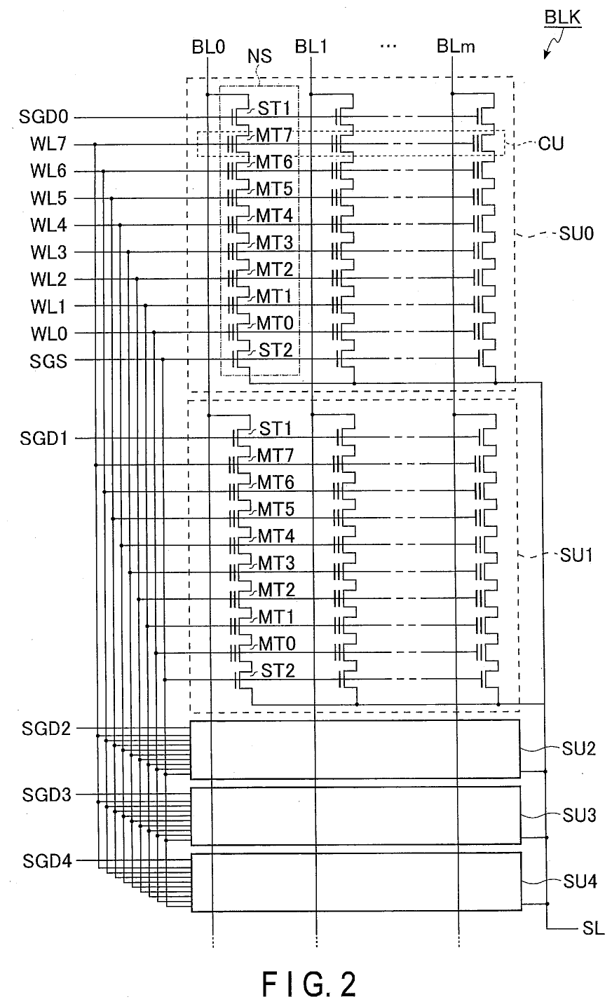

FIG. 2 shows an example of a circuit configuration of the memory cell array 10 included in the semiconductor memory device 1 according to the first embodiment, focusing on one of the blocks BLK in the memory cell array 10. As shown in FIG. 2, the block BLK contains, for example, five string units SU0 to SU4.

Each string unit SU includes a plurality of NAND strings NS respectively associated with bit lines BL0 to BLm (where m is an integer of 1 or more). Each NAND string NS includes, for example, memory cell transistors MT0 to MT7 and select transistors ST1 and ST2. Each memory cell transistor MT includes a control gate and a charge storage layer, and stores data in a nonvolatile manner. Each of the select transistors ST1 and ST2 is used for selection of a string unit SU in various operations.

In each NAND string NS, the memory cell transistors MT0 to MT7 are coupled in series. The drain of the select transistor ST1 is coupled to an associated bit line BL. The source of the select transistor ST1 is coupled to one end of a set of memory cell transistors MT0 to MT7 coupled in series. The drain of the select transistor ST2 is coupled to the other end of the set of memory cell transistors MT0 to MT7 coupled in series. The source of the select transistor ST2 is coupled to a source line SL.

The control gates of sets of memory cell transistors MT0 to MT7 in the same block BLK are respectively coupled to the word lines WL0 to WL7. The gates of a plurality of select transistors ST1 in the string unit SU0 are coupled to a select gate line SGD0. The gates of a plurality of select transistors ST1 in the string unit SU1 are coupled to a select gate line SGD1. The gates of a plurality of select transistors ST1 in the string unit SU2 are coupled to a select gate line SGD2. The gates of a plurality of select transistors ST1 in the string unit SU3 are coupled to a select gate line SGD3. The gates of a plurality of select transistors ST1 in the string unit SU4 are coupled to a select gate line SGD4. The gates of a plurality of select transistors ST2 are coupled to a select gate line SGS.

Different column addresses are respectively assigned to the bit lines BL0 to BLm. Each bit line BL is shared by the NAND strings NS, to which the same column address is assigned, among a plurality of blocks BLK. A set of word lines WL0 to WL7 is provided for each block BLK. A source line SL is, for example, shared among a plurality of blocks BLK.

A set of memory cell transistors MT commonly coupled to a word line WL in one string unit SU may be referred to as a “cell unit CU”. For example, the storage capacity of a cell unit CU including the memory cell transistors MT, each of which stores 1-bit data, is defined as “1-page data”. The cell unit CU may have a storage capacity of 2-page data or more in accordance with the number of bits of data stored in the memory cell transistors MT.

The circuit configuration of the memory cell array 10 included in the semiconductor memory device 1 according to the first embodiment is not limited to the above-described configuration. For example, the number of string units SU included in each block BLK and the numbers of memory cell transistors MT and select transistors ST1 and ST2 included in each NAND string NS may be any number.

### [1-2-2] Circuit Configuration of Row Decoder Module 15

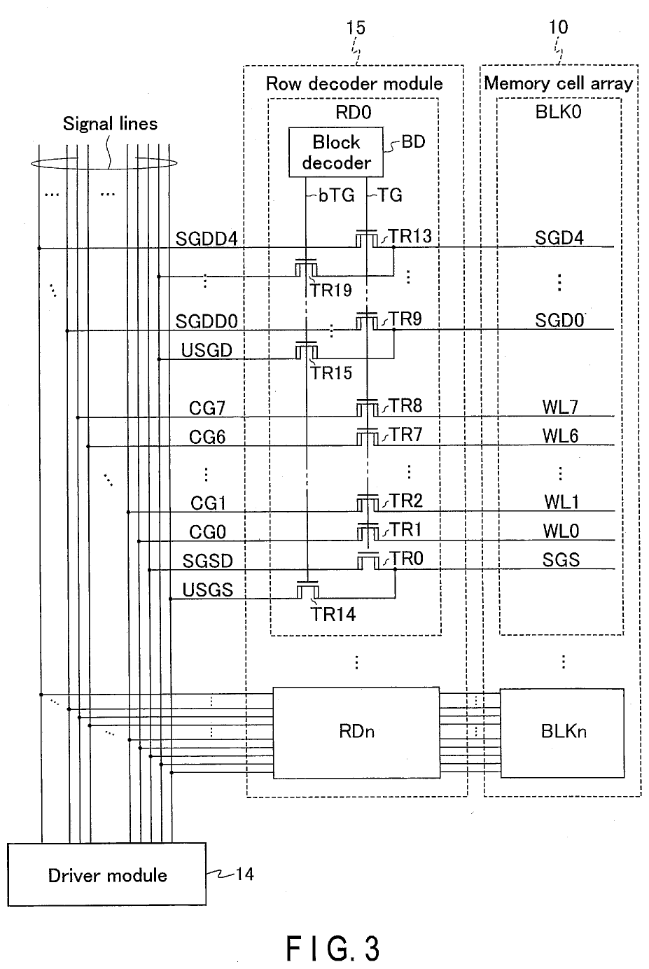

FIG. 3 shows an example of a circuit configuration of the row decoder module 15 included in the semiconductor memory device 1 according to the first embodiment. As shown in FIG. 3, the row decoder module 15 is coupled to the driver module 14, for example, via signal lines CGO to CG7, SGDD0 to SGDD3, SGSD, USGD, and USGS.

In addition, the row decoder module 15 includes row decoders RD0 to RDn respectively associated with the blocks BLK0 to BLKn. FIG. 3 shows only a detailed circuit configuration of the row decoder RD0. Each row decoder RD includes, for example, a block decoder BD, transfer gate lines TG and bTG, and transistors TR0 to TR19.

The block decoder BD decodes a block address, and applies a predetermined voltage to each of the transfer gate lines TG and bTG based on a decoding result. The voltage applied to the transfer gate line TG is complementary to the voltage applied to the transfer gate line bTG. In other words, an inversion signal of the transfer gate line TG is input to the transfer gate line bTG.

Each of the transistors TR0 to TR19 is an N-type MOS transistor having a high breakdown voltage. The gates of the transistors TR0 to TR13 are coupled to the transfer gate line TG. The gates of the transistors TR14 to TR19 are coupled to the transfer gate line bTG. Each of the transistors TR0 to TR19 is coupled between a signal line coupled to the driver module 14 and an interconnect provided in an associated block BLK.

Specifically, the drain of the transistor TR0 is coupled to the signal line SGSD. The source of the transistor TR0 is coupled to the select gate line SGS. The drains of the transistors TR1 to TR8 are coupled to the signal lines CGO to CG7, respectively. The sources of the transistors TR1 to TR8 are coupled to the word lines WL0 to WL7, respectively. The drains of the transistors TR9 to TR13 are coupled to the signal lines SGDD0 to SGDD4, respectively. The sources of the transistors TR9 to TR13 are coupled to the select gate lines SGD0 to SGD4, respectively. The drain of the transistor TR14 is coupled to the signal line USGS. The source of the transistor TR14 is coupled to the select gate line SGS. The drains of the transistors TR15 to TR19 are coupled to the signal line USGD. The sources of the transistors TR15 to TR19 are coupled to the select gate lines SGD0 to SGD4, respectively.

Namely, the signal lines CGO to CG7 are used as global word lines shared among a plurality of blocks BLK. The word lines WL0 to WL7 are used as local word lines provided for each block BLK. The signal lines SGDD0 to SGDD4 and SGSD are used as global select gate lines shared among a plurality of blocks BLK. The select gate lines SGD0 to SGD4 and SGS are used as local select gate lines provided for each block BLK.

During various operations, the block decoder BD corresponding to a selected block BLK applies an “H” level voltage and an “L” level voltage to the transfer gate lines TG and bTG, respectively, and the block decoder BD corresponding to a non-selected block BLK applies an “L” level voltage and an “H” level voltage to the transfer gate lines TG and bTG, respectively. Thereby, the row decoder module 15 can select a block BLK.

The circuit configuration of the row decoder module 15 included in the semiconductor memory device 1 according to the first embodiment is not limited to the above-described configuration. For example, the number of transistors TR included in the row decoder module 15 may be designed to correspond to the number of interconnects provided in each block ELK. Similarly, the number of signal lines coupling the row decoder module 15 and the driver module 14 can also be changed based on the number of transistors TR.

### [1-3] Structure of Semiconductor Memory Device 1

An example of a structure of the semiconductor memory device 1 according to the first embodiment will be described below. In the drawings to be referred to hereinafter, a direction in which the word lines WL extend is referred to as an “X direction”, a direction in which the bit lines BL extend is referred to as a “Y direction”, and a direction vertical to the surface of a semiconductor substrate 20 used for formation of the semiconductor memory device 1 is referred to as a “Z direction”. The plan views are provided with hatch patterns, as appropriate, to enhance the visibility of the drawings. This hatch pattern, however, may not necessarily relate to the materials or properties of the hatch-lined structural components. In the cross-sectional views, some configurations are omitted as appropriate to enhance the visibility of the drawings.

### [1-3-1] Planar Layout of Memory Cell Array 10

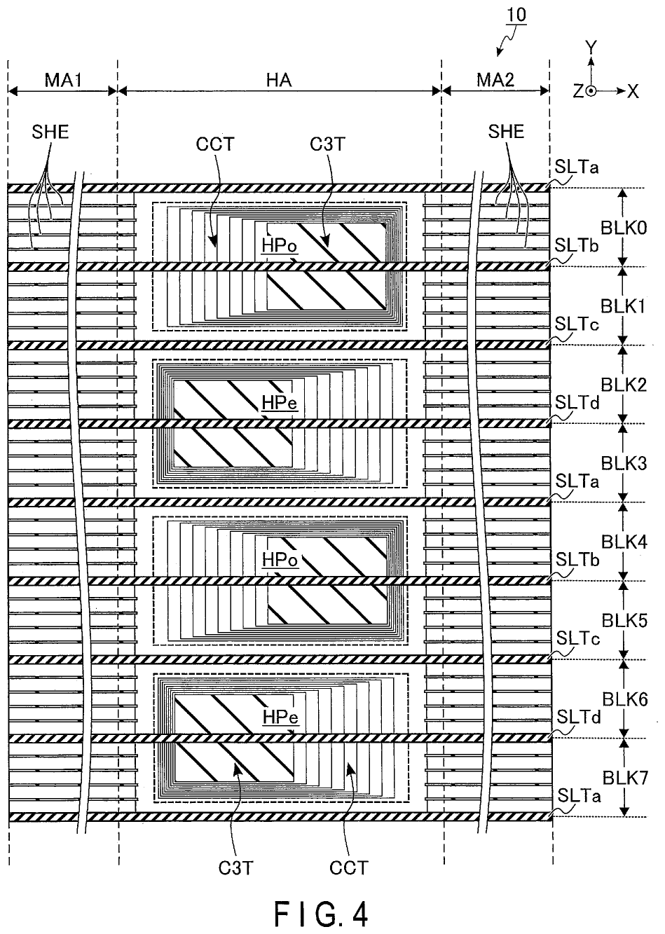

FIG. 4 shows an example of a planar layout of the memory cell array 10 included in the semiconductor memory device 1 according to the first embodiment, focusing on a region corresponding to eight blocks BLK0 to BLK7. As shown in FIG. 4, the memory cell array 10 includes a plurality of slits SLT and a plurality of slits SHE. The planar layout of the memory cell array 10 is, for example, divided into memory areas MA1 and MA2 and a hookup area HA in the X direction. Each of the memory areas MA1 and MA2 includes a plurality of NAND strings NS. The hookup area HA is disposed between the memory areas MA1 and MA2.

The slits SLT, each of which includes a portion provided so as to extend along the X direction, are arranged in the Y direction. Each of the slits SLT extends across the memory areas MA1 and MA2 and the hookup area HA in the X direction. The slit SLT has, for example, a structure in which an insulator or a plate-shaped contact is buried inside, and divides interconnects (e.g., the word lines WL0 to WL7 and the select gate lines SGD and SGS) that are adjacent to each other via the slit SLT. In this example, each of the regions sectioned by the slits SLT corresponds to one block BLK.

In the present specification, a slit SLT in contact with a block BLKk (k=4×i (i is an integer of 0 or more)) on the upper side of the drawing sheet is referred to as “SLTa”. A slit SLT in contact with a block BLK (k+1) on the upper side of the drawing sheet is referred to as “SLTb”. A slit SLT in contact with a block BLK (k+2) on the upper side of the drawing sheet is referred to as “SLTc”. A slit SLT in contact with a block BLK (k+3) on the upper side of the drawing sheet is referred to as “SLTd”. Namely, a plurality of sets of slits SLTa, SLTb, SLTc, and SLTd are arranged in the Y direction in the memory cell array 10.

The plurality of slits SHE are arranged in each of the memory areas MA1 and MA2. The slits SHE corresponding to the memory area MA1 are provided so as to intersect the memory area MA1, and are arranged in the Y direction. The slits SHE corresponding to the memory area MA2 are provided so as to intersect the memory area MA2, and are arranged in the Y direction. In this example, four slits SHE are disposed between any two adjacent slits SLT. The slit SHE has a structure in which an insulator is buried inside. The slit SHE divides interconnects (at least the select gate line SGD) that are adjacent to each other via the slit SHE. In this example, each of the areas sectioned by the slits SLT and SHE corresponds to one string unit SU.

The hookup area HA contains a plurality of hookup parts HP arranged in the Y direction. Each hookup part HP is disposed for every two blocks BLK. In other words, each hookup part HP is disposed in a region sandwiched between two slits SLT sandwiching two adjacent blocks BLK within the hookup area HA. Each hookup part HP overlaps a boundary between two adjacent block areas. Regarding a positional relationship between the hookup part HP and a set of two such block areas in the Y direction, the hookup part HP is provided within a partial area on the boundary side that the hookup part HP overlaps in each of the two block areas. Hereinafter, an odd-numbered hookup part HP is also referred to as “HPo”, and an even-numbered hookup part HP is also referred to as “HPe”. For example, the hookup part HPo is disposed in each of a set of blocks BLK0 and BLK1 and a set of blocks BLK4 and BLK5 within the hookup area HA. The hookup part HPe is disposed in each of a set of blocks BLK2 and BLK3 and a set of blocks BLK6 and BLK7 within the hookup area HA.

Each hookup part HP includes contact areas CCT and C3T arranged in the X direction. The contact area CCT includes a stepped structure of stacked interconnects (e.g., the word lines WL0 to WL7). The contact area C3T is an insulating area penetrating a structure of the stacked interconnects. The stacked interconnects run around the contact area C3T, and are electrically coupled in an area opposite to a boundary of a set of two block areas in the Y direction, between the memory areas MA1 and MA2. Specifically, in the block BLK0, the hookup part HP including the contact areas CCT and C3T is disposed closer to the slit SLTb side between the slits SLTa and SLTb in the Y direction, and the stacked interconnects within the memory area MA1 and the stacked interconnects within the memory area MA2 are continuously provided between the contact area C3T and the slit SLTa.

One slit SLT intersects each hookup part HP. The one slit SLT divides a stepped structure of stacked interconnects of two adjacent blocks BLK sharing a hookup part HP for each block BLK. Specifically, each of the hookup part HPo corresponding to the blocks BLK0 and BLK1 and the hookup part HPo corresponding to the blocks BLK4 and BLK5 is divided by the slit SLTb. Each of the hookup part HPe corresponding to the blocks BLK2 and BLK3 and the hookup part HPe corresponding to the blocks BLK6 and BLK7 is divided by the slit SLTd.

In the hookup area HA, the contact areas CCT and C3T of each hookup part HP are disposed alternately. Specifically, the arrangement of the contact areas CCT and C3T in the hookup part HPe is similar to that of the contact areas CCT and C3T in the hookup part HPo that is inverted in the X direction. Namely, in the hookup part HPo, the contact area CCT is disposed on the memory area MA1 side, and the contact area C3T is disposed on the memory area MA2 side. In the hookup part HPe, the contact area C3T is disposed on the memory area MA1 side, and the contact area CCT is disposed on the memory area MA2 side.

In the memory cell array 10, the layout shown in FIG. 4 is repeatedly disposed in the Y direction. The planar layout of the memory cell array 10 included in the semiconductor memory device 1 according to the first embodiment is not limited to the above-described layout. For example, the number of slits SHE disposed between any two adjacent slits SLT may be freely designed. The number of string units SU formed between any two adjacent slits SLT can be changed based on the number of slits SHE disposed between the adjacent slits SLT.

### [1-3-2] Structure of Memory Cell Array 10 in Memory Area MA

(Planar Layout of Memory Cell Array 10 in Memory Area MA)

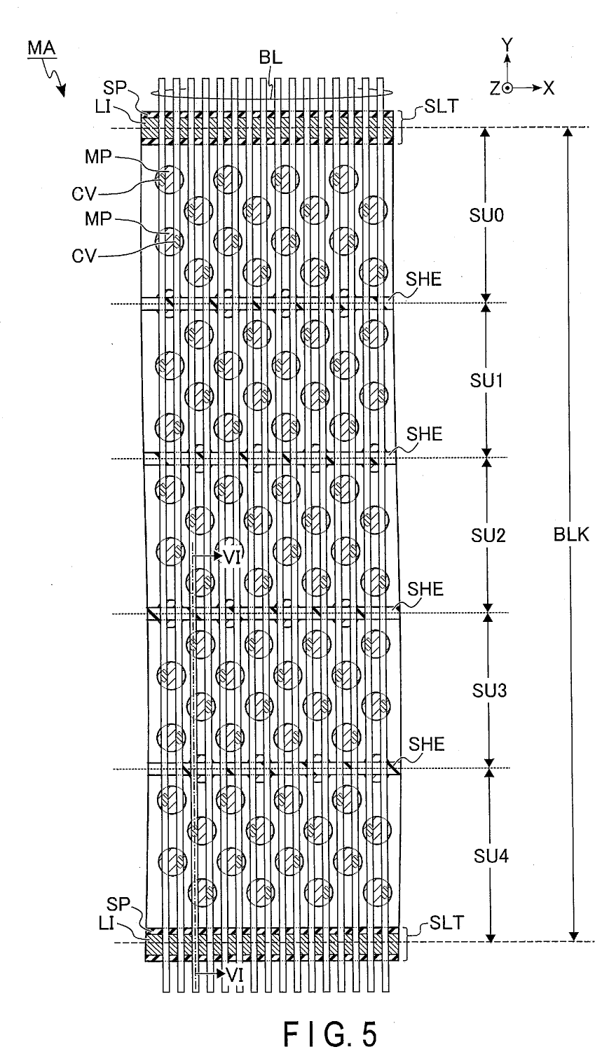

FIG. 5 shows an example of a detailed planar layout of the memory cell array 10, in the memory area MA, included in the semiconductor memory device 1 according to the first embodiment, focusing on a region including one block SLK (i.e., string units SU0 to SU4). As shown in FIG. 5, the memory cell array 10 includes a plurality of memory pillars MP, a plurality of contacts CV, and a plurality of bit lines BL, in the memory area MA. In addition, each slit SLT includes a contact LI and a spacer SP.

Each of the memory pillars MP functions as, for example, a single NAND string NS. The memory pillars MP are in, for example, a 24-row staggered arrangement in an area between two adjacent slits SLT. For example, a single slit SHE overlaps each set of the memory pillars MP in the fifth row, the tenth row, the fifteenth row, and the twentieth row, counting from the upper side of the drawing.

The bit lines BL, each of which extends in the Y direction, are arranged in the X direction. Each bit line BL is disposed so as to overlap at least one memory pillar MP in each string unit SU. In this example, two bit lines BL overlap each memory pillar MP. A contact CV is provided between a memory pillar MP and one of the bit lines BL that overlap the memory pillar MP. Each memory pillar MP is electrically coupled to a corresponding bit line BL by way of the contact CV.

A contact CV, however, is omitted between a memory pillar MP overlapped by the slit SHE and a bit line BL. In other words, a contact CV is omitted between a memory pillar MP in contact with two different select gate lines SGD and a bit line BL. The numbers and arrangement of memory pillars MP, slits SHE, etc. provided between any two adjacent slits SLT are not limited to the configuration described using FIG. 5, and may be modified as appropriate. The number of bit lines BL that overlap each memory pillar MP can be freely designed.

The contact LI is a conductor having a portion that extends in the X direction. The spacer SP is an insulator provided on a side surface of the contact LI. The contact LI and a conductor adjacent to the contact LI in the Y direction are distanced and insulated by the spacer SP. The contact LI is used as, for example, a part of the source line SL.

(Cross-Sectional Structure of Memory Cell Array 10 in Memory Area MA)

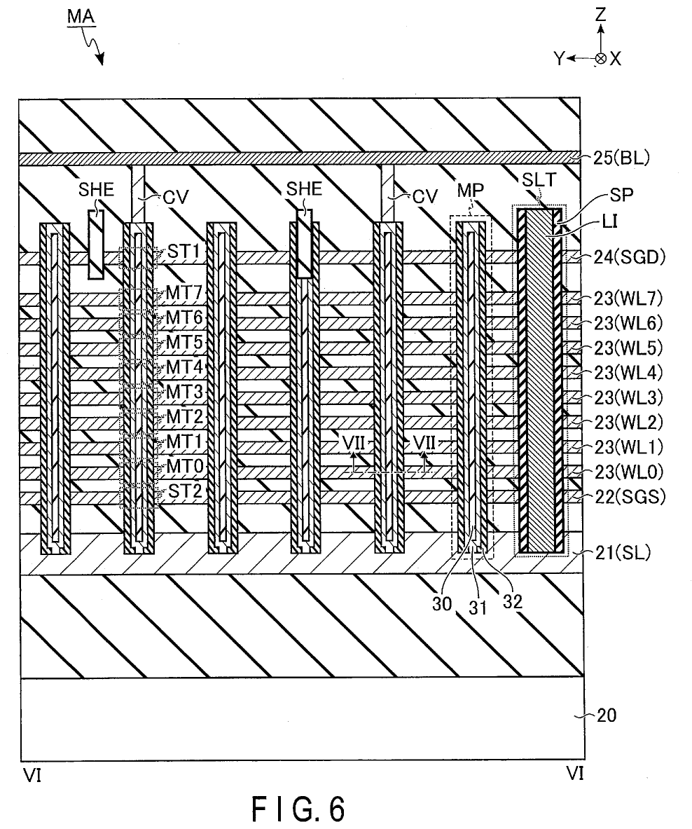

FIG. 6 is a cross-sectional view taken along line VI-VI in FIG. 5, showing an example of a cross-sectional structure of the memory cell array 10, in the memory area MA, included in the semiconductor memory device 1 according to the first embodiment. As shown in FIG. 6, the memory cell array 10 includes conductive layers 21 to 25. The conductive layers 21 to 25 are provided above the semiconductor substrate 20.

Specifically, the conductive layer 21 is provided above the semiconductor substrate 20, with an insulating layer interposed therebetween. In the insulating layer between the semiconductor substrate 20 and the conductive layer 21, for example, circuits corresponding to the row decoder module 15, the sense amplifier module 16, etc. are provided, although illustration thereof is omitted in the drawing. The conductive layer 21 is formed into, for example, a plate shape expanding along the XY plane, and is used as the source line SL. The conductive layer 21 contains, for example, phosphorous-doped silicon.

The conductive layer 22 is provided above the conductive layer 21, with an insulating layer interposed therebetween. The conductive layer 22 is formed into, for example, a plate shape expanding along the XY plane, and is used as a select gate line SGS. The conductive layer 22 contains, for example, tungsten.

Insulating layers and conductive layers 23 are alternately stacked above the conductive layer 22. The conductive layers 23 are each formed into, for example, a plate shape expanding along the XY plane. The stacked conductive layers 23 are respectively used as word lines WL0 to WL7 in ascending order from the semiconductor substrate 20 side. The conductive layers 23 contain, for example, tungsten.

The conductive layer 24 is provided above the uppermost conductive layer 23, with an insulating layer interposed therebetween. The conductive layer 24 is formed into, for example, a plate shape expanding along the XY plane. The conductive layer 24 is used as a select gate line SGD. The conductive layer 24 contains, for example, tungsten.

The conductive layer 25 is provided above the conductive layer 24 with an insulating layer interposed therebetween. The conductive layer 25 is, for example, formed into a linear shape extending in the Y direction, and is used as a bit line BL. Namely, a plurality of conductive layers 25 are arranged in the X direction in a region not shown in the drawing. The conductive layer 25 contains, for example, copper.

Each of the memory pillars MP extends in the Z direction, and penetrates the conductive layers 22 to 24. In addition, each of the memory pillars MP includes, for example, a core member 30, a semiconductor layer 31, and a stacked film 32. The core member 30 extends in the Z direction. For example, an upper end of the core member 30 is included in a layer above the uppermost conductive layer 24, and a lower end of the core member 30 is included in a layer in which the conductive layer 21 is provided. The semiconductor layer 31, for example, covers the periphery of the core member 30. Part of the semiconductor layer 31 is in contact with the conductive layer 21 at a lower portion of the memory pillar MP. The stacked film 32 covers side and bottom surfaces of the semiconductor layer 31, excluding the portion at which the semiconductor layer 31 is in contact with the conductive layer 21. The core member 30 contains, for example, an insulator such as silicon oxide. The semiconductor layer 31 contains, for example, silicon.

In the above-described structure of the memory pillar MP, a portion at which the memory pillar MP and the conductive layer 22 intersect each other functions as a select transistor ST2. A portion at which the memory pillar MP and each conductive layer 23 intersect each other functions as a memory cell transistor MT. A portion at which the memory pillar MP and the conductive layer 24 intersect each other functions as a select transistor ST1.

A pillar-shaped contact CV is provided on an upper surface of the semiconductor layer 31 in the memory pillar MP. In the illustrated area, two contacts CV respectively corresponding to two memory pillars MP, of the six memory pillars MP, are shown. To a memory pillar MP which does not overlap the slit SHE and to which a contact CV is not coupled in the illustrated area, a contact CV is coupled in an unillustrated area.

A single conductive layer 25, i.e., a single bit line BL, is in contact with upper surfaces of the contacts CV. In each space sectioned by the slits SLT and SHE, a single contact CV is coupled to the single conductive layer 25. This means, for example, that one memory pillar MP disposed between adjacent slits SLT and SHE and one memory pillar MP disposed between two adjacent slits SHE are electrically coupled to each conductive layer 25.

The slit SLT is formed into, for example, a shape expanding along the XZ plane, and divides the conductive layers 22 to 24. In the slit SLT, the contact LI is provided along the slit SLT, and the spacer SP is provided at least between the contact LI and the conductive layers 22 to 24. An upper end of the contact LI is included in a layer disposed between the conductive layer 24 and the conductive layer 25. A lower end of the contact LI is in contact with, for example, the conductive layer 21. The contact LI in the slit SLT may be omitted according to the structure of the memory cell array 10.

The slit SHE is formed into, for example, a plate shape expanding along the XZ plane, and divides the conductive layer 24. An upper end of the slit SHE is included in the layer disposed between the conductive layer 24 and the conductive layer 25. A lower end of the slit SHE is included in, for example, a layer disposed between the uppermost conductive layer 23 and the conductive layer 24. The slit SHE contains, for example, an insulator such as silicon oxide. Note that the upper end of the slit SHE and the upper end of the slit SLT may be designed to be at the same height or at different heights. In addition, the upper end of the slit SHE and an upper end of the memory pillar MP may be designed to be at the same height or at different heights.

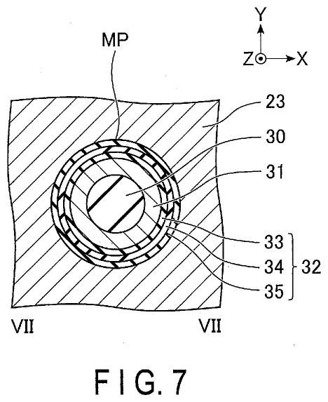

FIG. 7 is a plan view, taken along line VII-VII in FIG. 6, showing an example of a planar structure of the memory pillar MP in the semiconductor memory device 1 according to the first embodiment. More specifically, FIG. 7 shows a cross-sectional structure of the memory pillar MP in a layer that is parallel to the surface of the semiconductor substrate 20 and includes the conductive layer 23.

As shown in FIG. 7, the stacked film 32 includes, for example, a tunnel insulating film 33, an insulating film 34, and a block insulating film 35. In the layer including the conductive layer 23, the core member 30 is provided, for example, in the middle of the memory pillar MP. The semiconductor layer 31 surrounds the side surface of the core member 30. The tunnel insulating film 33 surrounds the side surface of the semiconductor layer 31. The insulating film 34 surrounds the side surface of the tunnel insulating film 33. The block insulating film 35 surrounds the side surface of the insulating film 34. The conductive layer 23 surrounds the side surface of the block insulating film 35.

The semiconductor layer 31 is used as a channel (current path) for the memory cell transistors MT0 to MT7 and the select transistors ST1 and ST2. Each of the tunnel insulating film 33 and the block insulating film 35 contains, for example, silicon oxide. The insulating film 34 is used as a charge storage layer of the memory cell transistors MT, and contains, for example, silicon nitride. In this manner, each of the memory pillars MP functions as a NAND string NS.

### [1-3-3] Structure of Memory Cell Array 10 in Hookup Area HA

Hereinafter, a structure of the memory cell array 10, in the hookup area HA, included in the semiconductor memory device 1 according to the first embodiment will be described. Note that the stacked interconnects and contacts provided in the hookup part HPo and those provided in the hookup part HPe have, for example, symmetric structures in the X direction. Since the structures of the hookup parts HPo and HPe are similar, an area including the hookup part HPo will be described below.

(Planar Layout of Memory Cell Array 10 in Hookup Area HA)

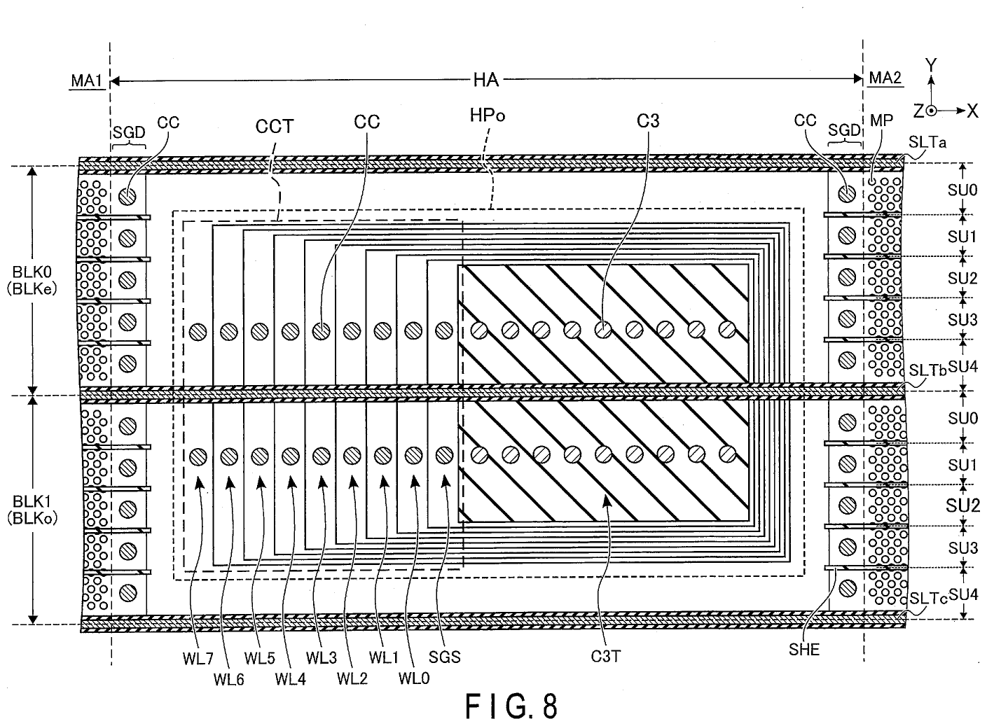

FIG. 8 shows an example of a detailed planar layout of the memory cell array 10, in the hookup area HA, included in the semiconductor memory device 1 according to the first embodiment, focusing on an area corresponding to two blocks BLK0 and BLK1 corresponding to the hookup area HPo. In addition, FIG. 8 shows a part of each of the memory areas MA1 and MA2 in the vicinity of the hookup area HA.

As shown in FIG. 8, in the hookup area HA, a select gate line SGD has a portion (terraced portion) not covered by the upper interconnect layers (conductive layers). In the contact area CCT, each of the select gate line SGS and word lines WL0 to WL7 has a terraced portion not covered by the upper conductive layers. The contact area C3T is an area that does not include the select gate lines SGS and SGD and word lines WL0 to WL7.

The shape of the portion not covered by the upper interconnect layers in the hookup area HA resembles a step, terrace, rimstone, etc. Specifically, steps are individually provided between the select gate line SGS and word line WL0, between the word lines WL0 and WL1, between the word lines WL6 and WL7, and between the word line WL7 and select gate line SGD. In this example, parts of the word lines WL0 to WL7 are provided in a staircase pattern having level differences in the X direction in the contact area CCT.

In the hookup area HA, the memory cell array 10 includes a plurality of contacts CC and a plurality of contacts C3. The contacts CC are respectively provided on the terraced portions of the select gate line SGS, word lines WL0 to WL7, and select gate lines SGD0 to SGD4 in each block BLK. The contacts C3 are provided in the contact area C3T so as to correspond to the select gate line SGS and word lines WL0 to WL7. The contacts CC and C3 provided in the hookup part HP and in an area of one of the blocks BLK are disposed in a straight line, for example. These contacts are not necessarily disposed in a straight line, but may be disposed to be offset vertically from one another.

Each stacked interconnect coupled to the NAND string NS is, for example, electrically coupled to the row decoder module 15 via a set of contacts CC and C3. In this example, each of the select gate line SGS and word lines WL0 to WL7 is coupled to the row decoder module 15 via a set of contacts CC and C3 disposed in the hookup area HA. The select gate line SGD may be coupled to the row decoder module 15 via a similar channel to that of the word line WL, or may be coupled to the row decoder module 15 via an area outside the hookup area HA.

A portion corresponding to the block BLK0 (BLKe) and a portion corresponding to the block BLK1 (BLKo) in the hookup part HPo have, for example, symmetric structures in the Y direction with reference to the slit SLTb. Similarly, a portion corresponding to the block BLK2 (BLKe) and a portion corresponding to the block BLK3 (BLKo) in the hookup part HPe (not shown) have, for example, symmetric structures in the Y direction with the slit SLTd as a symmetrical axis. Then, in the adjacent hookup parts HPo and HPe, the contact area CCT of the hookup part HPo and the contact area C3T of the hookup part HPe are adjacent to each other, and the contact area CCT of the hookup part HPe and the contact area C3T of the hookup part HPo are adjacent to each other.

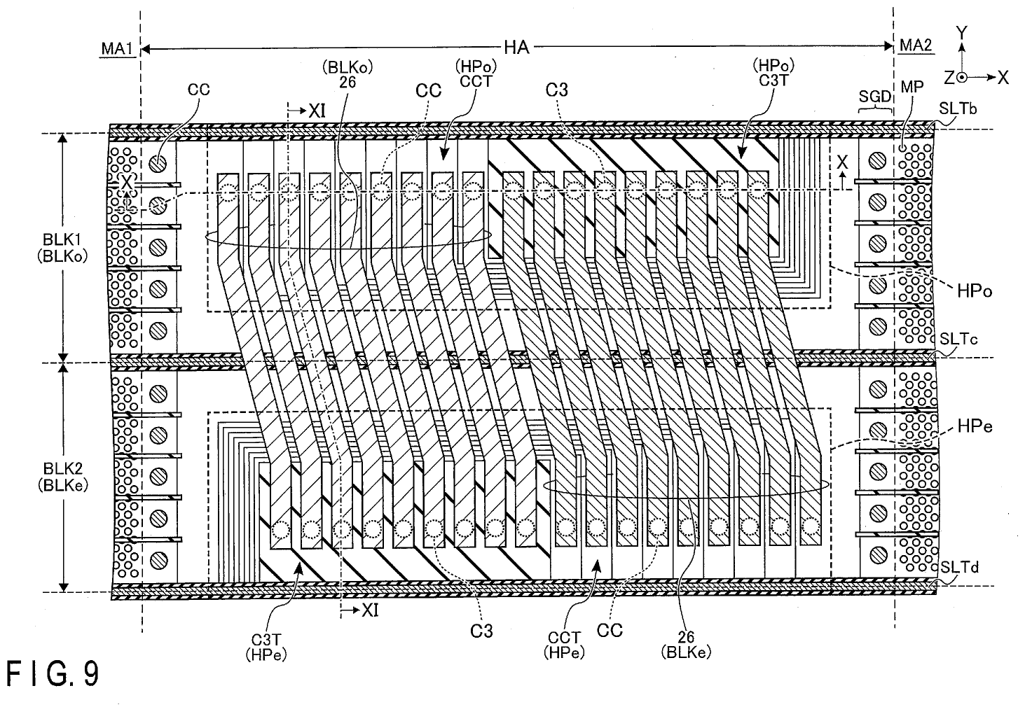

FIG. 9 shows an example of a detailed planar layout of the memory cell array 10, in the hookup area HA, included in the semiconductor memory device 1 according to the first embodiment, focusing on an area corresponding to the block BLK1 corresponding to the hookup part HPo and the block BLK2 corresponding to the hookup part HPe. In addition, interconnects used for coupling between the contacts CC and C3 are also shown in FIG. 9.

As shown in FIG. 9, the memory cell array 10 includes a plurality of conductive layers 26 in the hookup area HA. The conductive layers 26 are provided so as to correspond to the respective sets of contacts CC and C3. Then, the conductive layers 26 electrically couple the contacts CC corresponding to the block BLKo and the hookup part HPo and the contacts C3 corresponding to the block BLKe adjacent to the block BLKo and the hookup part HPe.

Specifically, nine contacts CC respectively coupled to the select gate line SGS and word lines WL0 to WL7 of the block BLK1 and included in the contact area CCT of the hookup part HPo are coupled to nine contacts C3 included in the contact area C3T of the hookup part HPe corresponding to the block BLK2, respectively. Each of these sets of contacts CC and C3 is, for example, electrically coupled via a single conductive layer 26. Then, the plurality of conductive layers 26 coupled to the stacked interconnects of the block BLK1 are arranged in the X direction.

Similarly, nine contacts CC respectively coupled to the select gate line SGS and word lines WL0 to WL7 of the block BLK2 and included in the contact area CCT of the hookup part HPe are coupled to nine contacts C3 included in the contact area C3T of the hookup part HPo corresponding to the block BLK1, respectively. Each of these sets of contacts CC and C3 is, for example, electrically coupled via a single conductive layer 26. Then, the plurality of conductive layers 26 coupled to the stacked interconnects of the block BLK2 are arranged in the X direction.

The above-described conductive layers 26 also electrically couple the contacts CC corresponding to the block BLKo and the hookup part HPo and the contacts C3 corresponding to the block BLKo adjacent to the block BLKe and the hookup part HPe in an unillustrated area. Namely, two blocks BLK corresponding to a hookup part HPo are coupled to the row decoder module 15 via two adjacent hookup parts HPe, respectively. Two blocks BLK corresponding to a hookup part HPe are coupled to the row decoder module 15 via two adjacent hookup parts HPo, respectively.

The plurality of conductive layers 26 coupled to the stacked interconnects of the block BLK1 and the plurality of conductive layers 26 coupled to the stacked interconnects of the block. BLK2 are provided in the same interconnect layer. In other words, the conductive layers 26 coupled to the stacked interconnects of the block BLK1 and the conductive layers 26 coupled to the stacked interconnects of the block BLK2 are arranged in the X direction. Namely, a plurality of conductive layers 26 included in adjacent hookup parts HPo and HPe are arranged in the X direction.

(Cross-Sectional Structure of Memory Cell Array 10 in Hookup Area HA)

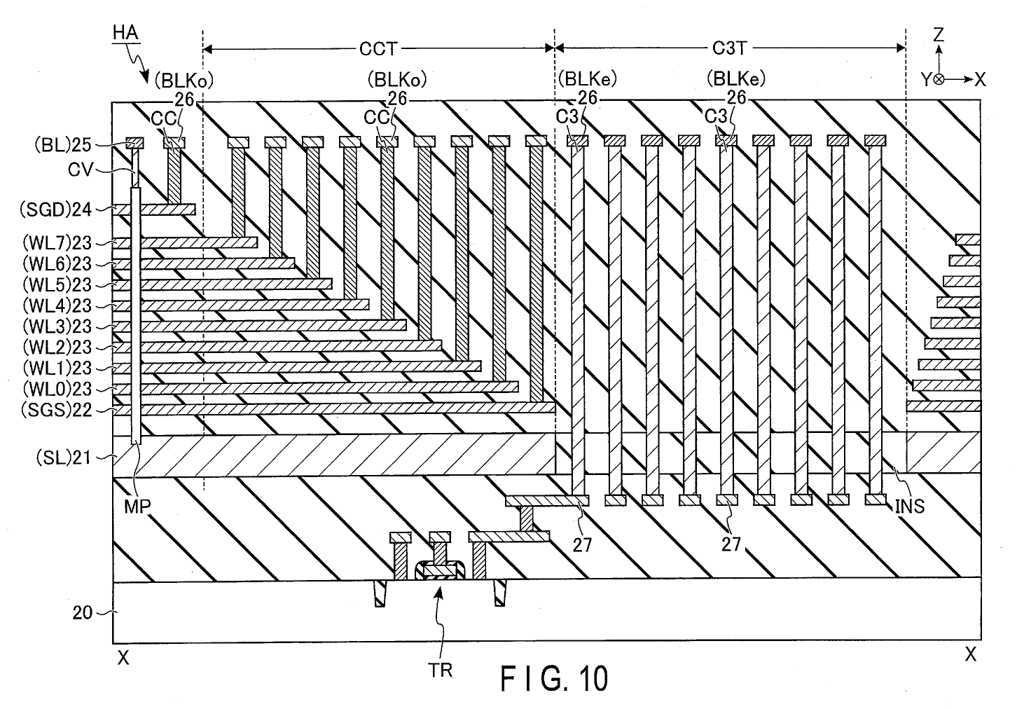

FIG. 10 is a cross-sectional view, taken along line X-X in FIG. 9, showing an example of a cross-sectional structure of the memory cell array 10, in the hookup area HA, included in the semiconductor memory device 1 according to the first embodiment. In addition, FIG. 10 also shows a cross section including the hookup part HPo and a part of the memory area MA in the vicinity of the hookup area HA.

As shown in FIG. 10, in the hookup area HA, parts of the conductive layers 22, 23, and 24 corresponding to the word lines WL and select gate lines SGD and SGS are provided in a staircase pattern. The contact area CCT includes a portion in which the conductive layers 22 and 23 are provided in a staircase pattern. The contacts CC are provided on the respective terraced portions of the select gate line SGS, word lines WL0 to WL7, and select gate line SGD. A single conductive layer 26 is provided on each contact CC. Thereby, the conductive layers 22, 23, and 24 and the conductive layers 26 associated therewith are electrically coupled via the contacts CC. The conductive layers 26 are included in, for example, a layer having the same height as that of the conductive layer 25.

In the contact area C3T, for example, a part of the conductive layer 21 corresponding to the source line SL is replaced with an insulating layer INS. Then, the plurality of contacts C3 penetrate through the insulating layer INS. Namely, each contact C3 is separated and electrically insulated from the conductive layer 21. In addition, the memory cell array 10 in the hookup area HA includes a plurality of conductive layers 27 provided so as to respectively correspond to the conductive layers 26. Each conductive layer 27 is coupled to the transistor TR included in the row decoder module 15.

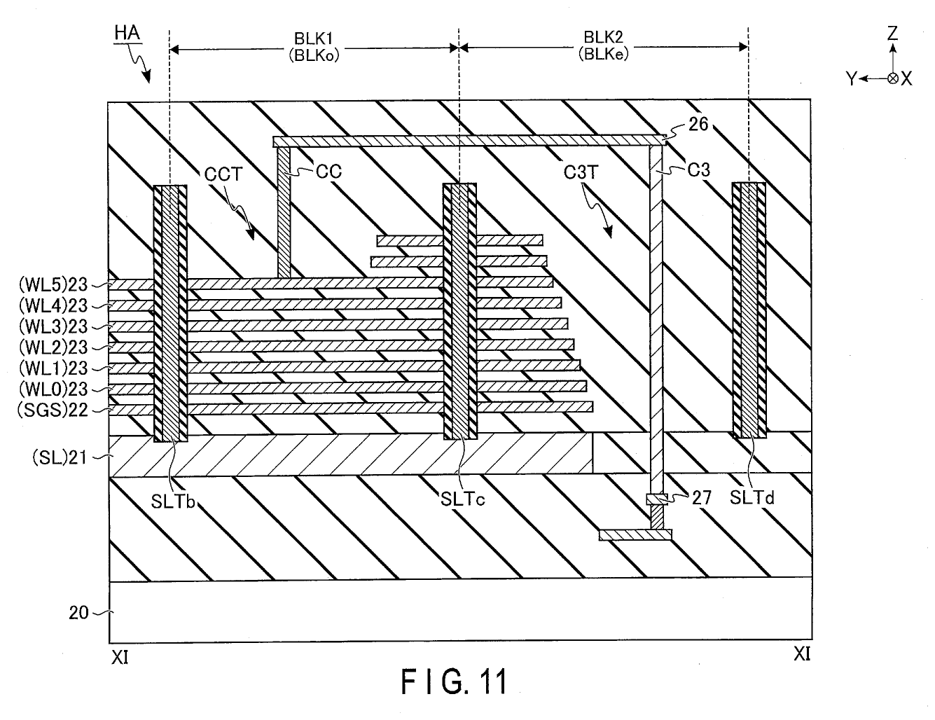

FIG. 11 is a cross-sectional view, taken along line XI-XI in FIG. 9, showing an example of a cross-sectional structure of the memory cell array 10, in the hookup area HA, included in the semiconductor memory device 1 according to the first embodiment. In addition, FIG. 11 shows a cross section including the hookup parts HPo and HPe, and a configuration associated with coupling between the word line WL5 of the block BLK1 and the row decoder module 15.

As shown in FIG. 11, one contact CC is coupled on the terraced portion of the conductive layer 23 corresponding to the word line WL5 of the block BLK1. The contact CC is coupled to the conductive layer 26 having a portion extending from the block BLK1 toward the block BLK2. To the conductive layer 26, a contact C3 provided in the contact area C3T corresponding to the block BLK2 is coupled. The contact C3 is coupled to the conductive layer 27 coupled to an associated transistor TR (not shown).

Thus, the conductive layer 23 corresponding to the word line WL5 of the block BLK1 is electrically coupled to the transistor TR in the row decoder module 15 via the contact CC in the block BLK1, the contact C3 in the block BLK2, and the conductive layers 26 and 27. The other stacked interconnects may be coupled to the row decoder module 15 in the same manner as the above-described word line WL5. In this example, a set of contacts CC and C3 is coupled without via interconnects in a layer above the conductive layer 26. In this way, it is preferable that only one interconnect layer be used for coupling between the contacts CC and C3.

### [1-4] Advantageous Effects of First Embodiment

The above-described semiconductor memory device 1 according to the first embodiment can suppress the manufacturing costs of the semiconductor memory device 1. Hereinafter, details of the advantageous effects of the semiconductor memory device 1 according to the first embodiment will be described using a comparative example. In a semiconductor memory device comprising three-dimensionally stacked memory cells, stacked interconnects such as word lines WL are formed by, for example, replacement processing of the stacked interconnects. Briefly speaking, insulating layers and sacrificial members are formed in an alternating manner in the replacement processing of the stacked interconnects. By selectively removing the sacrificial members and forming a conductor in the space from which the sacrificial members are removed, stacked interconnects such as the word lines WL are formed. Then, a structure in which such stacked interconnects are disposed above the peripheral circuit such as a row decoder module is known.

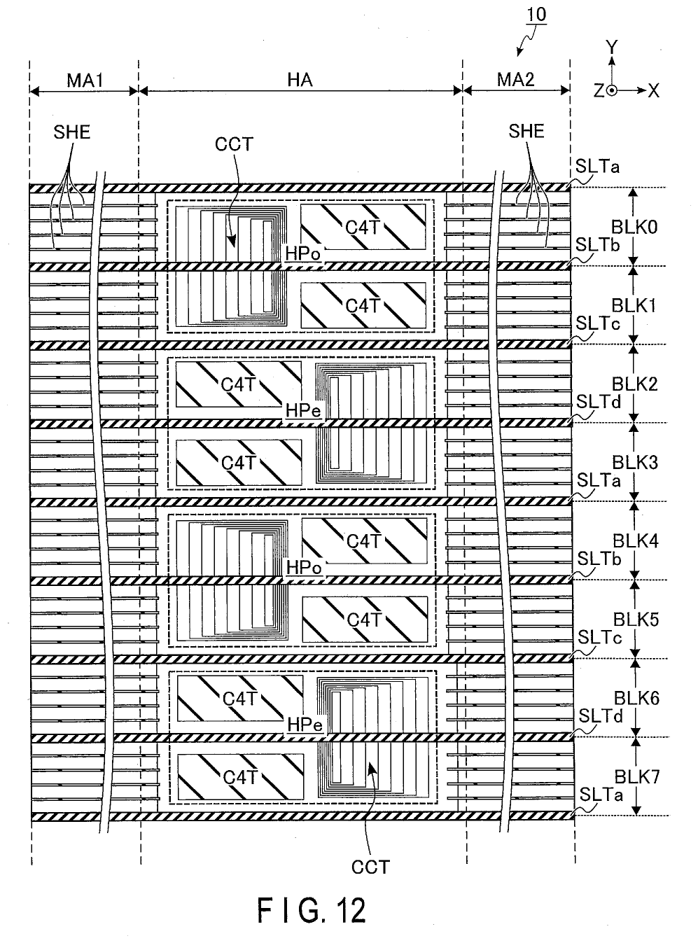

FIG. 12 shows an example of a planar layout of the memory cell array 10 in the semiconductor memory device 1 according to a comparative example of the first embodiment, showing a region similar to that shown in FIG. 4. As shown in FIG. 12, the memory cell array 10 in the comparative example of the first embodiment includes the hookup area HA including the hookup parts HPo and HPe. The hookup part HP in the comparative example of the first embodiment includes the contact area CCT and two contact areas C4T.

The contact area CCT in the comparative example of the first embodiment has a configuration in which the contact area C3T is omitted from the hookup part HP of the first embodiment. The contact area C4T is disposed between adjacent slits SLT in an area from which the contact area C3T of the first embodiment is omitted. Then, in the comparative example of the first embodiment, although illustration is omitted, the stacked interconnects and the row decoder module 15 are coupled via adjacent blocks BLK in the same manner as in the first embodiment.

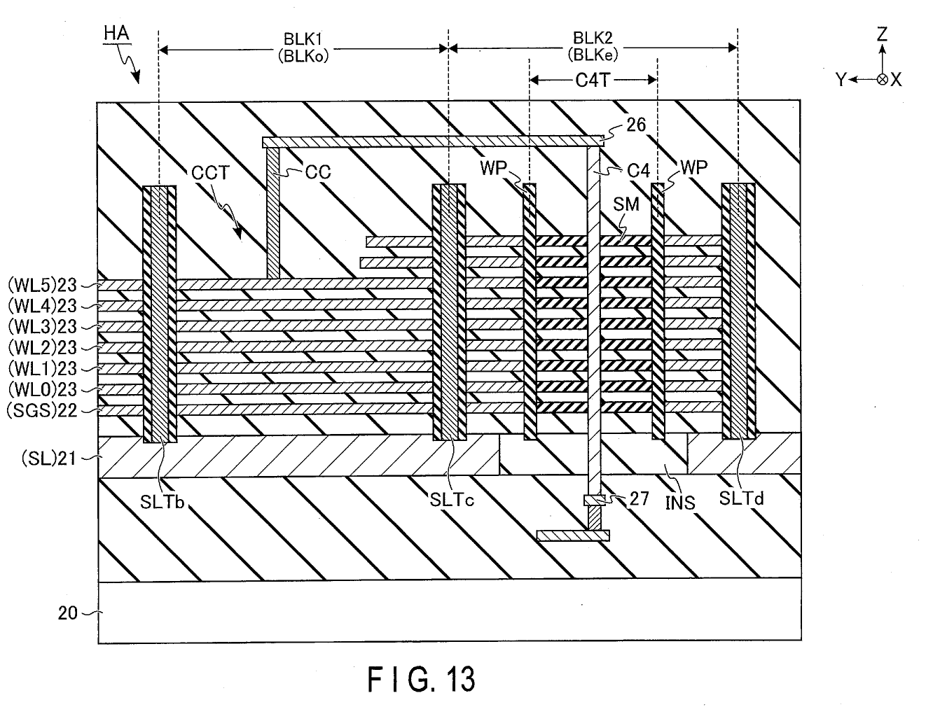

FIG. 13 shows an example of a cross-sectional structure of the memory cell array 10 in the semiconductor memory device 1 according to the comparative example of the first embodiment, showing a region similar to that shown in FIG. 11. As shown in FIG. 13, the contact area C4T in the comparative example of the first embodiment is, for example, sandwiched by two wall parts WP. The wall part WP has a structure in which an insulator is embedded therein, for example. The area sandwiched by the two wall parts WP includes portions where the sacrificial members SM are not replaced with conductors by the replacement processing. Then, a contact C4 is provided to penetrate the portions. The contact C4 couples the conductive layers 26 and 27 in the same manner as the contact C3 of the first embodiment.

The semiconductor memory device 1 according to the comparative example of the first embodiment has a structure in which the contact areas CCT of the hookup parts HP are disposed in an alternating manner in the hookup area HA as described above. Thus, the semiconductor memory device 1 according to the comparative example of the first embodiment can couple the contacts CC and C4 by the conductive layer 26 having a simple shape with a portion extending in the Y direction, thereby simplifying the interconnect layout within the hookup area HA.

On the other hand, in the semiconductor memory device 1 according to the comparative example of the first embodiment, the contact area C4T in which the contact C4 penetrating the stacked interconnects can be disposed is formed by providing the wall parts WP. In order to form the contact area C4T, at least a process of forming slits corresponding to the wall parts WP and a process of filling the slits in with an insulator are necessary. Namely, in the comparative example of the first embodiment, the manufacturing costs may increase with the increase in manufacturing processes due to the formation of the contact area C4T.

In contrast, in the semiconductor memory device 1 according to the first embodiment, each hookup part HP includes the contact area C3T from which the lowermost portion of the stepped structure is removed. The contact area C3T can be formed as an extension of the process of forming the stepped structure of the contact area CCT. Specifically, for the formation of the contact area C3T, a mask for forming the stepped structure of the contact area CCT is appropriable.

As a result, the semiconductor memory device 1 according to the first embodiment can reduce the number of manufacturing processes as compared to the comparative example of the first embodiment, and can suppress the manufacturing costs of the semiconductor memory device. In addition, the semiconductor memory device 1 according to the first embodiment can couple the contacts CC and C3 by the conductive layer 26 having a simple shape with a portion extending in the Y direction, thereby simplifying the interconnect layout within the hookup area HA, in the same manner as the comparative example of the first embodiment.

### [2] Second Embodiment

A semiconductor memory device 1 according to a second embodiment has a configuration in which the structure in the hookup area HA is modified with respect to the semiconductor memory device 1 according to the first embodiment. Hereinafter, points in the semiconductor memory device 1 according to the second embodiment that are different from the first embodiment will be described.

### [2-1] Structure of Semiconductor Memory Device 1

(Planar Layout of Memory Cell Array 10 in Hookup Area HA)

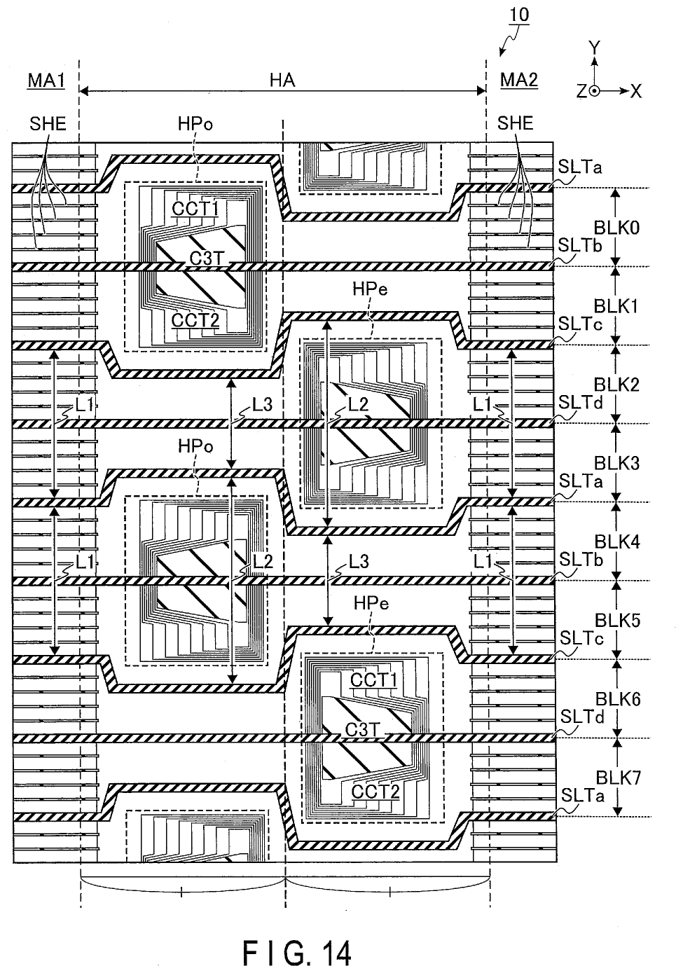

FIG. 14 shows an example of a planar layout of a memory cell array 10, in a hookup area HA, included in the semiconductor memory device 1 according to the second embodiment, showing a region corresponding to eight blocks BLK0 to BLK7. In the following descriptions, an “upper side” indicates an upper side on the paper where the drawing is described. A “lower side” indicates a lower side on the paper where the drawing is described. A “left side” indicates a left side on the paper where the drawing is described. A “right side” indicates a right side on the paper where the drawing is described.

As shown in FIG. 14, a structure of a hookup part HP of the memory cell array 10 of the second embodiment is different from that of the memory cell array 10 of the first embodiment. Specifically, the width of each of the hookup parts HPo and HPe in the X direction is smaller than half of the width of the hookup area HA in the X direction. The width of each of the hookup parts HPo and HPe in the Y direction is larger than the length between two slits SLT sandwiching two blocks BLK within the memory area MA. Each hookup part HPo is disposed on the left side with respect to a middle line of the hookup area HA. Each hookup part HPe is disposed on the right side with respect to the middle line of the hookup area HA. In other words, the odd-numbered hookup parts HPo are arranged in the Y direction. The even-numbered hookup parts HPe are arranged in the Y direction. Then, an even-numbered hookup part HPe is not included between adjacent odd-numbered hookup parts HPo. An odd-numbered hookup part HPo is not included between adjacent even-numbered hookup parts HPe.

Each hookup part HP includes contact areas CCT1, CCT2, and C3T. The contact area CCT1 is disposed on an upper side in the hookup part. HP, and associated with the odd-numbered block BLKe. The contact area CCT2 is disposed on a lower side in the hookup part HP, and associated with the even-numbered block BLKo. The contact area C3T is sandwiched between the contact areas CCT1 and CCT2 in the Y direction. The layout of the contact areas CCT1, CCT2, and C3T in the hookup part HPe is, for example, similar to the layout of the contact areas CCT1, CCT2, and C3T in the hookup part HPo that is inverted in the X direction.

In addition, in the second embodiment, as the width of each hookup part HP in the Y direction increases, the slits SLTa and SLTc have a crank shape in the hookup area HA. Specifically, the slit SLTa has a shape bending to the upper side at a portion adjacent to the hookup part HPo, and bending to the lower side at a portion adjacent to the hookup part HPe. On the other hand, the slit SLTc has a shape bending to the lower side at a portion adjacent to the hookup part HPo, and bending to the upper side at a portion adjacent to the hookup part HPe.

More specifically, a portion of the slit SLTa that is provided on the left side within the hookup area HA is offset to the upper side with respect to a portion of the slit SLTa that is provided in the memory area MA1. A portion of the slit SLTa that is provided on the right side within the hookup area HA is offset to the lower side with respect to a portion of the slit SLTa that is provided in the memory area MA2. On the other hand, a portion of the slit SLTc that is provided on the left side within the hookup area HA is offset to the lower side with respect to a portion of the slit SLTc that is provided in the memory area MA1. A portion of the slit SLTc that is provided on the right side within the hookup area HA is offset to the upper side with respect to a portion of the slit SLTc that is provided in the memory area MA2.

For example, in the slits SLTa and SLTc sandwiching the blocks BLK0 and BLK1, the crank shape of the slit SLTc coincides with the crank shape of the slit SLTa that is inverted with the slit SLTb between the slits SLTa and SLTc as a symmetrical axis. Similarly, in the slits SLTc and SLTa sandwiching the blocks BLK2 and BLK3, the crank shape of the slit SLTa coincides with the crank shape of the slit SLTc that is inverted with the slit SLTd between the slits SLTc and SLTa as a symmetrical axis.

As described above, a distance between the adjacent slits SLTa and SLTc with one hookup part HP interposed therebetween in the Y direction changes according to the position within the memory cell array 10. For example, a distance between the slits SLTa and SLTc sandwiching the blocks BLK4 and BLK5 is defined as “L1” in the memory areas MA1 and MA2, “L2” at a portion adjacent to the memory area MA1 within the hookup area HA, and “L3” at a portion adjacent to the memory area MA2 within the hookup area HA. In this case, L2 is larger than L1, and L3 is smaller than L1.

In addition, in this example, a distance between the slits SLTa and SLTc sandwiching the blocks BLK2 and BLK3 is designed to be “L1” in the memory areas MA1 and MA2, “L3” at a portion adjacent to the memory area MA1 within the hookup area HA, and “L2” at a portion adjacent to the memory area MA2 within the hookup area HA. In this case, L2+L3=L1×2. That is, within the memory areas MA and the hookup area HA, a distance between the adjacent slits SLTa and a distance between the adjacent slits SLTc, including the cranked portions, are approximately equal.

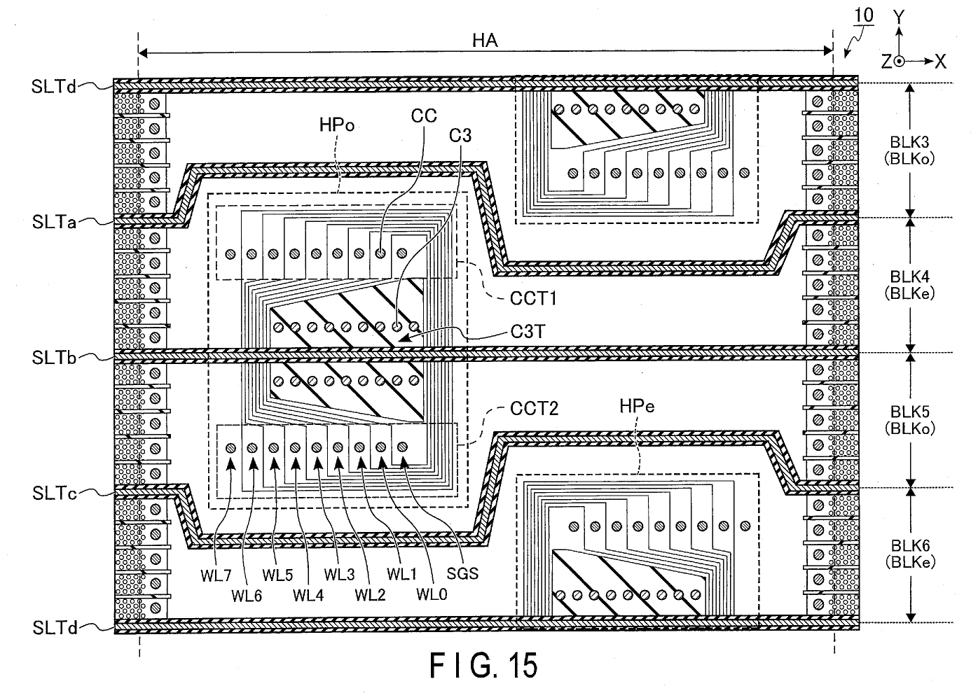

FIG. 15 shows an example of a detailed planar layout of the memory cell array 10, in the hookup area HA, included in the semiconductor memory device 1 according to the second embodiment, showing a region corresponding to four blocks BLK3 to BLK6. Since the layout of the hookup part HPo is similar to that of the hookup part HPe, the hookup part HPo will be described below.

As shown in FIG. 15, in the hookup part HPo, each of the contact areas CCT1 and CCT2 includes a similar stepped structure to that of the first embodiment. The stepped structure includes, for example, the terraced portions of the select gate line SGS and word lines WL0 to WL7. Then, the contacts CC are respectively provided on the terraced portions of the select gate line SGS and word lines WL0 to WL7 included in the contact area CCT1. The contacts CC are respectively provided on the terraced portions of the select gate line SGS and word lines WL0 to WL7 included in the contact area CCT2.

The contact area C3T is an insulating area penetrating a structure of stacked interconnects in the same manner as in the first embodiment. In the second embodiment, the contact area C3T is divided by the slit SLTb. Then, the contact area C3T includes a plurality of contacts C3 respectively corresponding to the plurality of contacts CC within the contact area CCT1 in an area above the slit SLTb, and includes a plurality of contacts C3 respectively corresponding to the plurality of contacts CC within the contact area CCT2 in an area below the slit SLTb.

The contacts CC within the contact area CCT1 are, for example, arranged in the X direction. The contacts CC within the contact area CCT2 are, for example, arranged in the X direction. The contacts C3 corresponding to the block BLK4 within the contact area C3T are, for example, arranged in the X direction. The contacts C3 corresponding to the block BLK5 within the contact area C3T are, for example, arranged in the X direction. These contacts are not necessarily disposed in a straight line, but may be disposed to be offset vertically from one another.

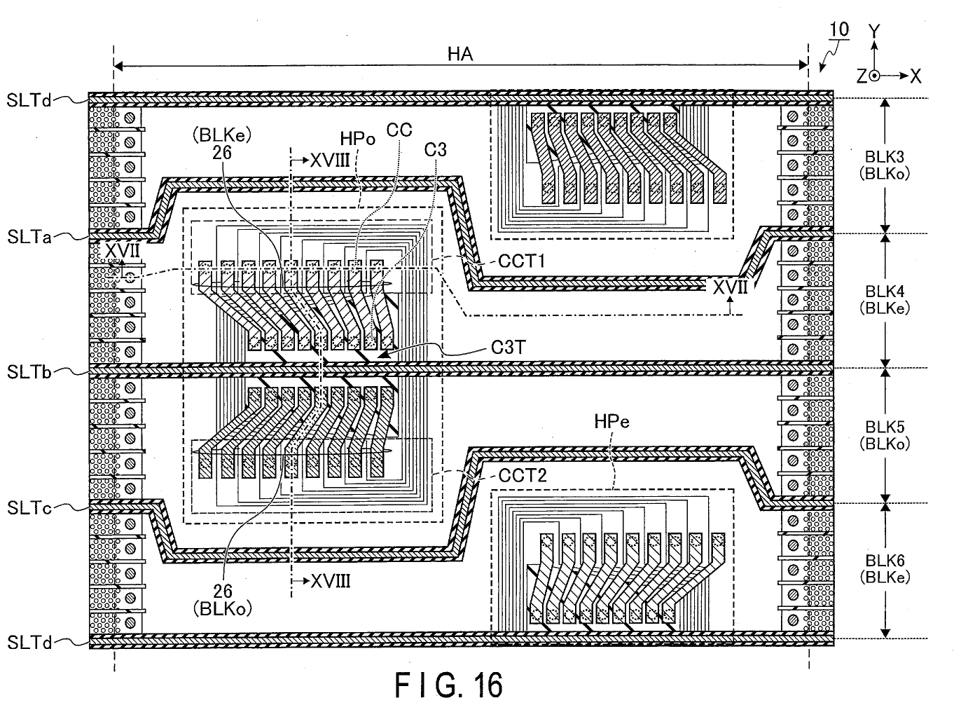

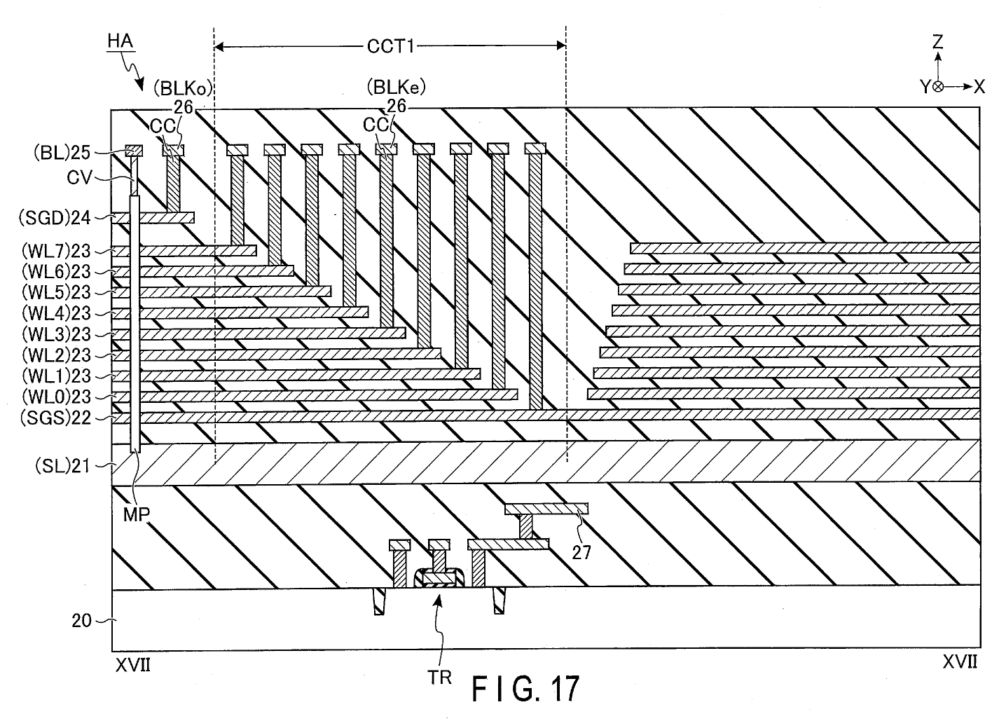

FIG. 16 shows an example of a detailed planar layout of the memory cell array 10, in the hookup area HA, included in the semiconductor memory device 1 according to the second embodiment, showing a region similar to that shown in FIG. 15.

As shown in FIG. 16, the hookup part HPo includes a plurality of conductive layers 26 corresponding to the block BLK4 (BLKe) in an area above the slit SLTb. Each of the conductive layers 26 electrically couples a set of contacts CC and C3 in the area above the slit SLTb. The conductive layers 26 provided in the area above the slit SLTb are arranged in the X direction.

Similarly, the hookup part HPo includes a plurality of conductive layers 26 corresponding to the block BLK5 (BLKo) in the area below the slit SLTb. Each of the conductive layers 26 electrically couples a set of contacts CC and C3 in the area below the slit SLTb. The conductive layers 26 provided in the area below the slit SLTb are arranged in the X direction.

In addition, a set of conductive layers 26 corresponding to the block BLK4 (BLKe) and a set of conductive layers 26 corresponding to the block ELKS (BLKo) are arranged in the Y direction within the same hookup part HPo.

As described above, the conductive layers 26 corresponding to the block BLKe are disposed in an area between the adjacent slits SLTa and SLTb, and the conductive layers 26 corresponding to the block BLKo are disposed in an area between the adjacent slits SLTb and SLTc. A configuration of the hookup part HPe is, for example, similar to the configuration of the hookup part HPo that is inverted with the Y axis as a symmetrical axis.

(Cross-Sectional Structure of Memory Cell Array 10 in Hookup Area HA)

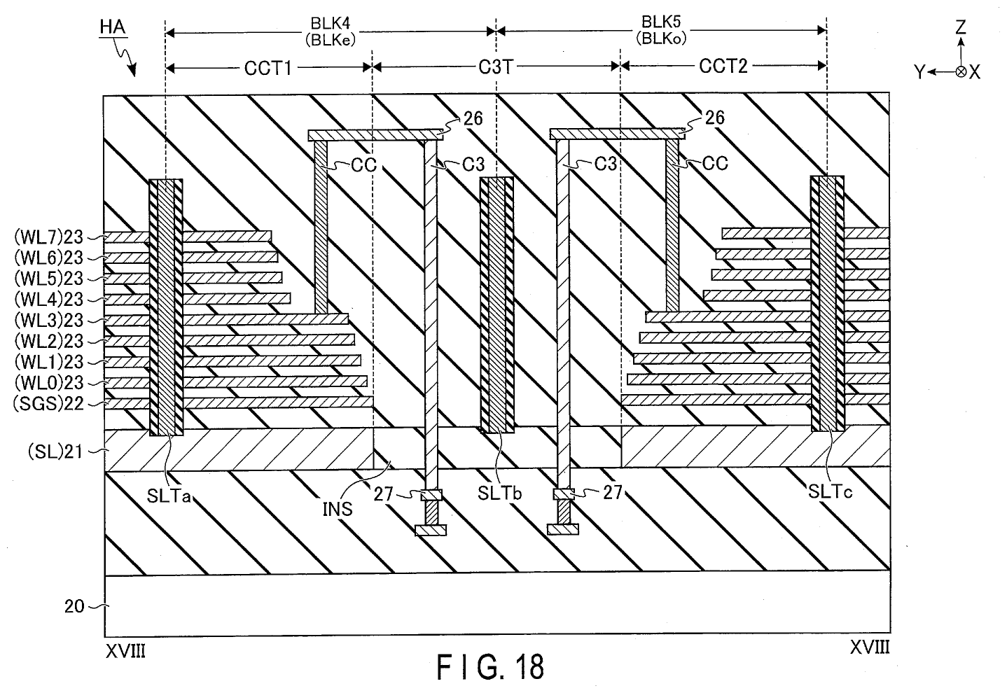

FIGS. 17 and 18 show an example of a cross-sectional structure of the memory cell array 10, in the hookup area HA, included in the semiconductor memory device 1 according to the second embodiment. In addition, FIG. 17 shows a cross section of the memory cell array 10, taken along line. XVII-XVII in FIG. 16. FIG. 18 shows a cross section of the memory cell array 10, taken along line XVIII-XVIII in FIG. 16.

As shown in FIG. 17, the contacts CC are respectively provided on the terraced portions of the select gate line SGS and word lines WL0 to WL7 in the contact area CCT1 in the same manner as in the first embodiment. Similarly, the contacts CC are respectively provided on the terraced portions of the select gate line SGS and word lines WL0 to WL7 also in the contact area CCT2. Then, a single conductive layer 26 is provided on each contact CC. Thereby, each of the conductive layers 22 and 23 and the associated conductive layer 26 are electrically coupled via the contact CC.

As shown in FIG. 18, each conductive layer 26 is included in an area sectioned by an associated block BLK and adjacent slits SLT. Specifically, for example, the conductive layer 26 associated with the word line WL3 of the block BLK4 is included in an area sectioned by the slits SLTa and SLTb sandwiching the block BLK4. The conductive layer 26 associated with the word line WL3 of the block BLK5 is included in an area sectioned by the slits SLTb and SLTc sandwiching the block BLK5. Then, each conductive layer 26 is coupled to a conductive layer 27 coupled to a transistor TR (not shown) via the contact C3 disposed in the contact area C3T.

In this way, the word lines WL in each block BLK are electrically coupled to the transistors TR within the row decoder module 15 via the contacts CC and C3 and conductive layer 26 disposed in an area sectioned by the block BLK and adjacent slits SLT. Note that, in this example, a set of contacts CC and C3 is coupled without via interconnects in a layer above the conductive layer 26 in the same manner as in the first embodiment. As such, it is preferable that only one interconnect layer is used for the coupling between the contacts CC and C3. The other configurations of the semiconductor memory device 1 according to the second embodiment are the same as those of the first embodiment.

### [2-2] Advantageous Effects of Second Embodiment

As described above, the semiconductor memory device 1 according to the second embodiment includes a plurality of hookup parts HP disposed in an alternating manner right and left in the hookup area HA. The width of the hookup part HP in the X direction in the second embodiment is smaller than that of the hookup part HP in the X direction in the first embodiment. In the second embodiment, the slits SLTa and SLTc have a crank shape in order to secure an area for forming a multi-row stepped structure.

Thereby, the semiconductor memory device 1 according to the second embodiment can arrange an interconnect (conductive layer 26) for coupling a set of contacts CC and C3 without straddling the blocks BLK. As a result, the semiconductor memory device 1 according to the second embodiment can reduce an area in which the plurality of conductive layers 26 are provided in the hookup area HA, and mitigate the degree of difficulty of interconnect layout in the hookup area HA.

### [3] Third Embodiment

A semiconductor memory device 1 according to a third embodiment has a configuration in which the structure in the hookup part HP is modified with respect to the semiconductor memory device 1 according to the second embodiment. Hereinafter, points in the semiconductor memory device 1 according to the third embodiment that are different from the first and second embodiments will be described.

### [3-1] Structure of Semiconductor Memory Device 1

(Planar Layout of Memory Cell Array 10 in Hookup Area HA)

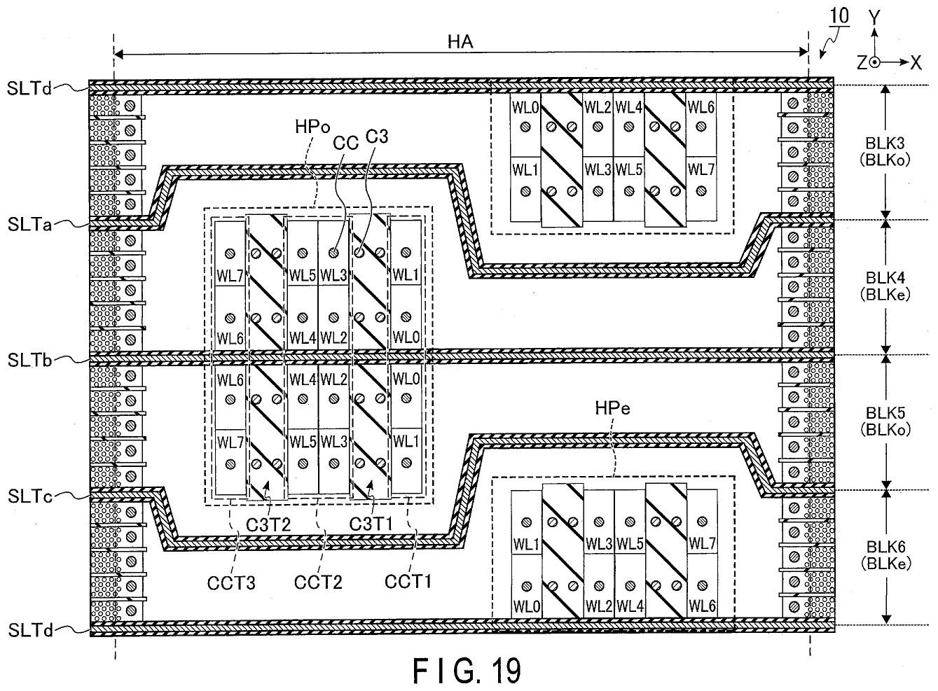

FIG. 19 shows an example of a detailed planar layout of the memory cell array 10, in the hookup area HA, included in the semiconductor memory device 1 according to the third embodiment, showing a region corresponding to four blocks BLK3 to BLK6. Note that in the present embodiment, illustration of a configuration relating to coupling of a contact to the select gate line SGS is omitted to simplify the explanation.

As shown in FIG. 19, a structure of a hookup part HP of the memory cell array 10 of the third embodiment is different from that of the memory cell array 10 of the second embodiment. Specifically, each hookup part HP is divided into contact areas CCT1, CCT2, CCT3, C3T1, and C3T2 in the X direction. The contact areas CCT1 to CCT3 are arranged in the X direction. The contact area C3T1 is disposed between the contact areas CCT1 and CCT2. The contact area C3T2 is disposed between the contact areas CCT2 and CCT3.

In addition, the contact areas CCT1, CCT2, CCT3, C3T1, and C3T2 of the hookup part HPo are divided by the slit SLTb. In an area above the slit SLTb, the contact area CCT1 includes the terraced portions of the word lines WL0 and WL1 arranged in the Y direction, the contact area CCT2 includes the terraced portions of the word lines WL2 and WL3 arranged in the Y direction and the terraced portions of the word lines WL4 and WL5 arranged in the Y direction, and the contact area CCT3 includes the terraced portions of the word lines WL6 and WL7 arranged in the Y direction. The respective terraced portions of the word lines WL0, WL2, WL4, and WL6 corresponding to the block BLK4 (BLKe) are arranged in the X direction. The respective terraced portions of the word lines WL1, WL3, WL5, and WL7 corresponding to the block BLK4 (BLKe) are arranged in the X direction. The respective terraced portions of the word lines WL2 and WL4 corresponding to the block BLK4 (BLKe) are adjacent. The respective terraced portions of the word lines WL3 and WL5 corresponding to the block BLK4 (BLKe) are adjacent.

In other words, in the area of the hookup part HPo above the slit SLTb, a two-row stepped structure of stacked interconnects is provided. Then, the two-row stepped structure is appropriately divided by the contact areas C3T. In this example, in the contact area CCT2 disposed on an inner side of the hookup part HPo, the terraced portions are provided for two stages in the X direction. In each of the contact areas CCT1 and CCT3 disposed at ends of the hookup part HPo in the X direction, the terraced portions are provided for one stage in the X direction.

Then, the contacts CC are respectively provided on the terraced portions of the contact areas CCT1, CCT2, and CCT3 and word lines WL0 to WL7 above the slit SLTb in the hookup part HPo. The contact area C3T1 above the slit SLTb in the hookup part HPo includes a plurality of contacts C3 respectively corresponding to the word lines WL0 to WL3. The contact area C3T2 above the slit SLTb in the hookup part HPo includes a plurality of contacts C3 respectively corresponding to the word lines WL4 to WL7.

The contacts CC respectively corresponding to the word lines WL0 to WL3 are respectively adjacent to the contacts C3 within the contact area C3T1. The contacts CC respectively corresponding to the word lines WL4 to WL7 are respectively adjacent to the contacts C3 within the contact area C3T2. A configuration of the hookup part HPo below the slit SLTb is, for example, similar to the configuration of the hookup part HPo above the slit SLTb that is inverted with the slit SLTb as a symmetrical axis.

In addition, in the same manner as the hookup part HPo, the contact areas CCT1, CCT2, CCT3, C3T1, and C3T2 of the hookup part HPe are divided by the slit SLTd. The other configurations of the hookup part HPe are, for example, similar to the configurations of the hookup part HPo that are inverted in the X direction. Namely, in an area of the hookup part HPe above the slit SLTd, terraced portions of stacked interconnects associated with the block BLKe and contacts CC and C3 associated with the block BLKe are provided. In an area below the slit SLTd in the hookup part HPe, terraced portions of stacked interconnects associated with the block BLKo and contacts CC and C3 associated with the block BLKo are provided.

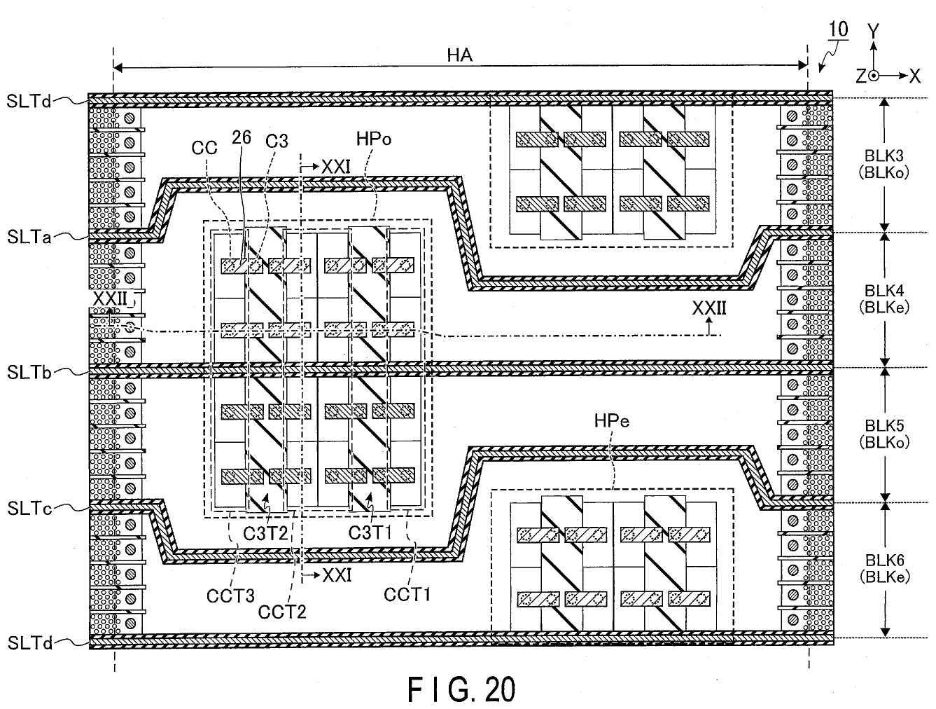

FIG. 20 shows an example of a detailed planar layout of the memory cell array 10, in the hookup area HA, included in the semiconductor memory device 1 according to the third embodiment, showing an area similar to that shown in FIG. 19.

As shown in FIG. 20, a plurality of conductive layers 26 corresponding to the block BLK4 (BLKe) are included in an area above the slit SLTb. Each of the conductive layers 26 electrically couples a set of contacts CC and C3 in the area above the slit SLTb. For example, the conductive layers 26 provided in the area above the slit SLTb and respectively corresponding to the word lines WL0, WL2, WL4, and WL6 are arranged in the X direction. The conductive layers 26 provided in the area above the slit SLTb and respectively corresponding to the word lines WL1, WL3, WL5, and WL7 are arranged in the X direction.

In addition, two conductive layers 26 respectively coupled to the word lines WL0 and WL1 are included in the contact areas CCT1 and C3T1. Two conductive layers 26 respectively coupled to the word lines WL2 and WL3 are included in the contact areas CCT2 and C3T1. Two conductive layers 26 respectively coupled to the word lines WL4 and WL5 are included in the contact areas CCT2 and C3T2. Two conductive layers 26 respectively coupled to the word lines WL6 and WL7 are included in the contact areas CCT3 and C3T2.

As described above, the conductive layers 26 corresponding to the block BLKe are disposed in an area between the adjacent slits SLTa and SLTb. A configuration of the hookup part HPo below the slit SLTb is, for example, similar to a configuration of the hookup part HPo above the slit SLTb that is inverted with the slit SLTb as a symmetrical axis. In addition, a configuration of the hookup part HPe is, for example, similar to the configuration of the hookup part HPo that is inverted in the X direction.

(Cross-Sectional Structure of Memory Cell Array 10 in Hookup Area HA)

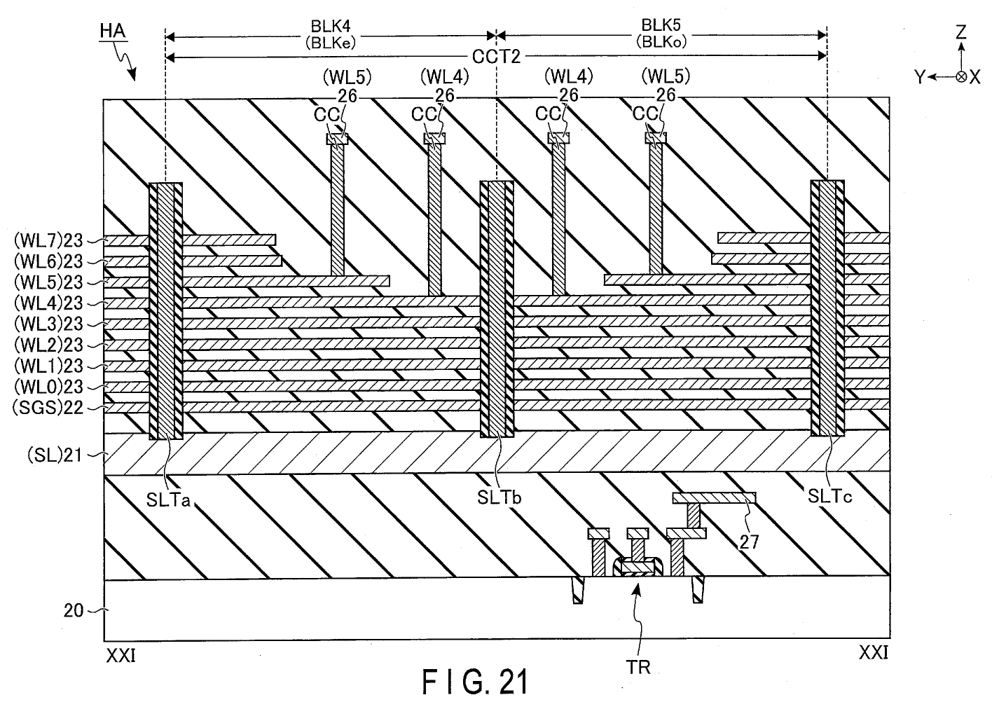

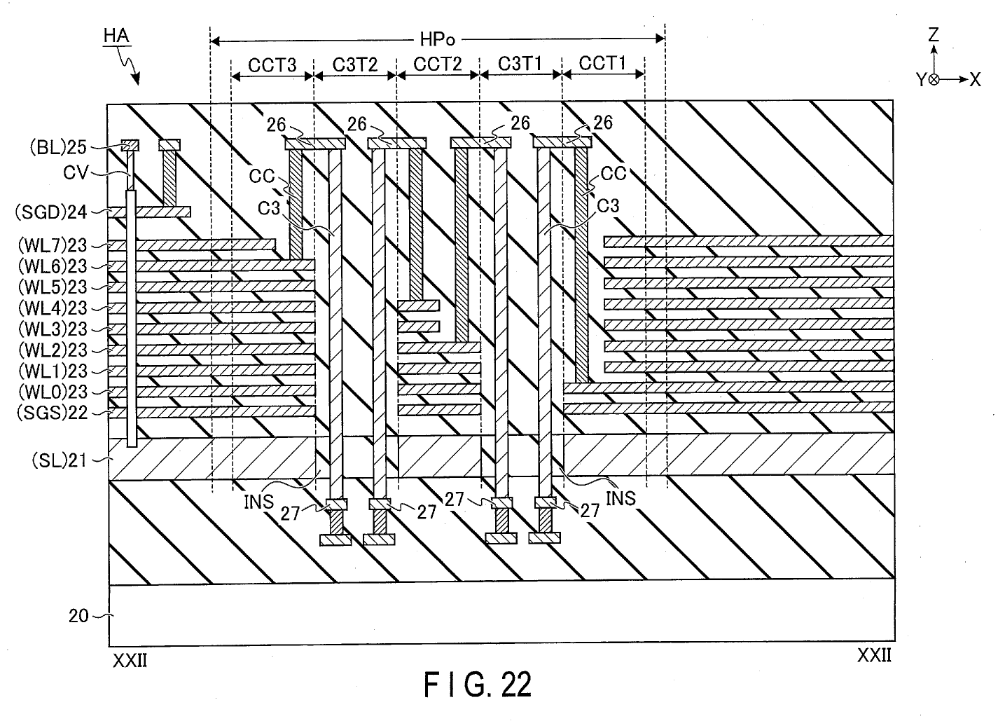

FIGS. 21 and 22 show examples of cross-sectional structures of the memory cell array 10, in the hookup area HA, included in the semiconductor memory device 1 according to the third embodiment. In addition, FIG. 21 shows a cross section of the memory cell array 10, taken along line XXI-XXI in FIG. 20. FIG. 22 shows a cross section of the memory cell array 10, taken along line XXII-XXII in FIG. 20.

As shown in FIG. 21, in the memory cell array 10 in the third embodiment, the terraced portions of the word lines WL form a one-stage level difference in the Y direction. Specifically, the respective terraced portions of the word lines WL4 and WL5 of the block BLK4 (BLKe) are adjacent. The respective terraced portions of the word lines WL4 and WL5 of the block BLK5 (BLKo) are adjacent. In addition, the terraced portion of the word line WL4 of the block BLK4 and the terraced portion of the word line WL4 of the block BLK5 are adjacent via the slit SLTb.

In an area sandwiched between the slits SLTa and SLTb adjacent to the block BLK4 (BLKe) within the contact area CCT2, a contact CC coupled to the word line WL4 and a contact CC coupled to the word line WL5 are arranged in the Y direction. Similarly, in an area sandwiched between the slits SLTc and SLTb adjacent to the block BLK5 (BLKo) within the contact area CCT2, a contact CC coupled to the word line WL4 and a contact CC coupled to the word line WL5 are arranged in the Y direction. Then, a single conductive layer 26 is provided on each contact CC. Thereby, each conductive layer 23 and an associated conductive layer 26 are electrically coupled via the contact CC.

As shown in FIG. 22, in the memory cell array 10 in the third embodiment, the terraced portions of the word lines WL form two-stage level differences in the X direction. Specifically, the terraced portion of the word line WL2 and the terraced portion of the word line WL0 are adjacent via the contact area C3T1. The terraced portion of the word line WL4 and the terraced portion of the word line WL2 are adjacent within the contact area CCT2. The terraced portion of the word line WL6 and the terraced portion of the word line WL4 are adjacent via the contact area C3T2.

Each conductive layer 26 couples the contacts CC and C3 in the adjacent contact areas CCT and C3T. The contact C3 couples associated conductive layers 26 and 27 in the contact area C3T1 or C3T2. The contact C3 is insulated from the stacked interconnects such as the word lines WL. For example, in the contact areas C3T1 and C3T2, the conductive layer 21 is replaced with the insulating layer INS. Note that the insulating layer INS may be provided at least at a portion where the contact C3 penetrates. Then, each conductive layer 23 is coupled to a conductive layer 27 coupled to a transistor TR (not shown) via the contact C3 disposed in the contact area C3T.

As described above, the word lines WL in each block BLK are electrically coupled to the transistors TR within the row decoder module 15 via the contacts CC and C3 and conductive layers 26 disposed in an area sectioned by the block BLK and adjacent slits SLT. Note that, in this example, a set of contacts CC and C3 is coupled without via interconnects in a layer above the conductive layer 26 in the same manner as in the first embodiment. In this way, it is preferable that only one interconnect layer be used for the coupling between the contacts CC and C3. The other configurations of the semiconductor memory device 1 according to the third embodiment are the same as those of the second embodiment.

### [3-2] Advantageous Effects of Third Embodiment

As described above, the semiconductor memory device 1 according to the third embodiment includes a multi-row stepped structure for each block ELK in the hookup area HA. In addition, in the third embodiment, the slits SLTa and SLTc have a crank shape similar to that in the second embodiment in order to secure an area for forming a multi-row stepped structure.

Thereby, the semiconductor memory device 1 according to the third embodiment can make the width of the stepped structure provided in the hookup part HP in the X direction smaller than that in the first embodiment. As a result, the semiconductor memory device 1 according to the third embodiment can suppress the area of the hookup area HA as compared to that in the first embodiment, and reduce the chip area of the semiconductor memory device 1.

Note that in the third embodiment, a case where the stacked interconnect is provided in a two-row staircase pattern in an area corresponding to each block ELK has been illustrated, but the configuration is not limited thereto. The stacked interconnect may be provided in a staircase pattern of three rows or more. Also in such a case, a contact area C3T is appropriately inserted between a plurality of contact areas CCT arranged in the X direction so that the contacts CC and C3 can be coupled by the conductive layer 26 in the same manner as in the third embodiment.

### [4] Fourth Embodiment

A semiconductor memory device 1 according to a fourth embodiment includes a configuration in which slits STS are added to the hookup part HP with respect to the semiconductor memory device 1 according to the second embodiment. Hereinafter, points in the semiconductor memory device 1 according to the fourth embodiment that are different from the second embodiment will be described.

### [4-1] Structure of Semiconductor Memory Device 1

(Planar Layout of Memory Cell Array 10 in Hookup Area HA)

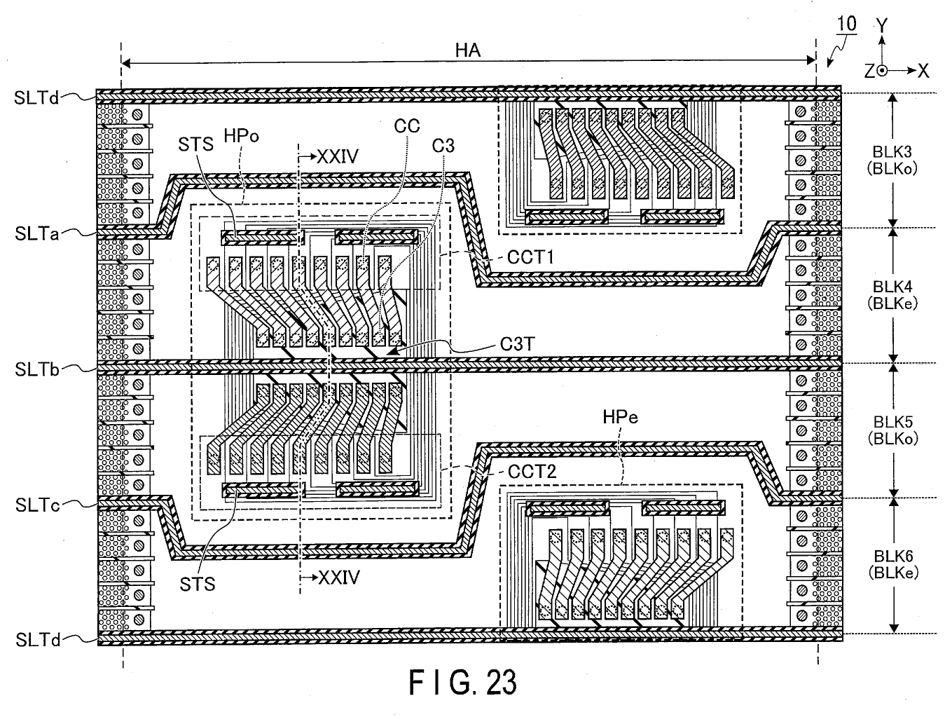

FIG. 23 shows an example of a detailed planar layout of a memory cell array 10, in a hookup area HA, included in the semiconductor memory device 1 according to the fourth embodiment, showing a region similar to that shown in FIG. 16 described in the second embodiment.

As shown in FIG. 23, the memory cell array 10 in the fourth embodiment has a configuration in which a plurality of slits STS are added to the hookup area HA of the memory cell array 10 described in the second embodiment. Specifically, each hookup part HP includes a plurality of slits STS. A structure of the slit STS is, for example, the same as that of the slit SLT, and has a portion extending in the X direction. The slits STS are appropriately disposed apart from a plurality of contacts CC in an area where a distance between the slits SLTa and SLTc is large.

In this example, two slits STS arranged in the X direction are provided in each of an area of the hookup part HPo above the slit SLTb and an area of the hookup part HPo below the slit SLTb. Similarly, two slits STS arranged in the X direction are provided in each of an area of the hookup part HPe above the slit SLTd and an area of the hookup part HPe below the slit SLTd. The width of the slit STS is preferably designed to be equal to or less than that of the slit SLT in order to shorten a time for replacement processing.

(Cross-Sectional Structure of Memory Cell Array 10 in Hookup Area HA)

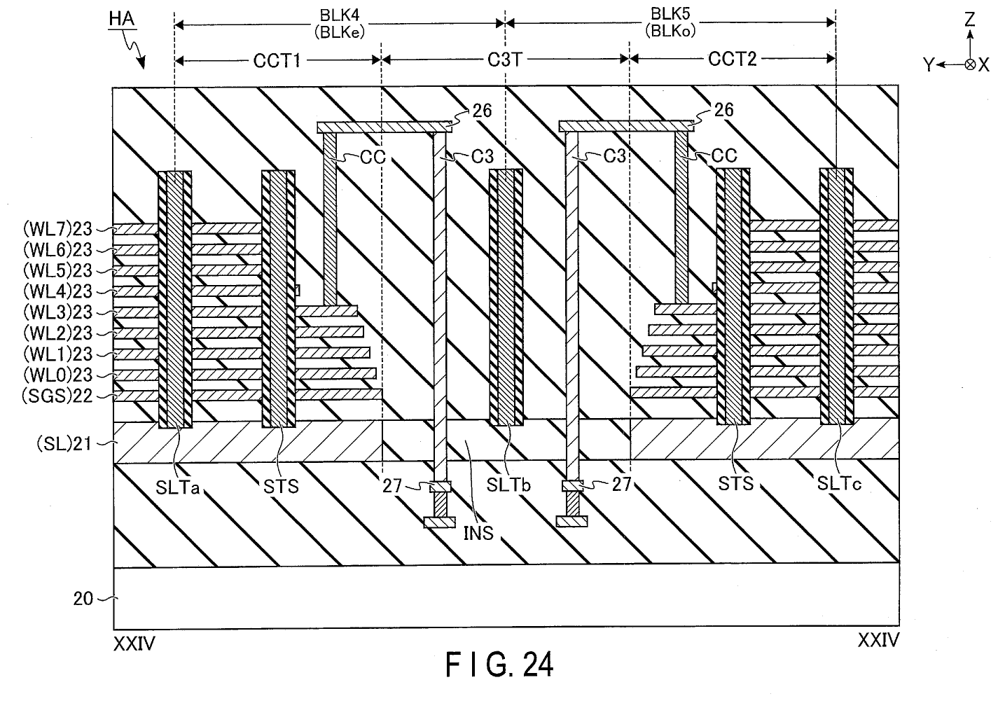

FIG. 24 shows an example of a cross-sectional structure of the memory cell array 10, in the hookup area HA, included in the semiconductor memory device 1 according to the fourth embodiment, showing a cross section, taken along line XXIV-XXIV in FIG. 23.

As shown in FIG. 24, the cross-sectional structure of the memory cell array 10 in the hookup area HA in the fourth embodiment is such that the slits STS are added to FIG. 18 described in the second embodiment. The height of the slit STS is approximately equal to that of the slit SLT, and the structure of the slit STS is, for example, similar to that of the slit SLT. Note that there is a case where the contact LI is not formed in the slit STS depending on the width of the slit STS. In addition, the slit STS may or may not be in contact with the conductive layer 21. An insulating layer INS may be provided at a bottom portion of the slit STS. The other configurations of the semiconductor memory device 1 according to the fourth embodiment are the same as those of the second embodiment.

### [4-2] Advantageous Effects of Fourth Embodiment

According to the above-described semiconductor memory device 1 according to the fourth embodiment, the manufacturing costs of the semiconductor memory device 1 can be lowered. Hereinafter, details of advantageous effects of the semiconductor memory device 1 according to the fourth embodiment will be described using a comparative example.

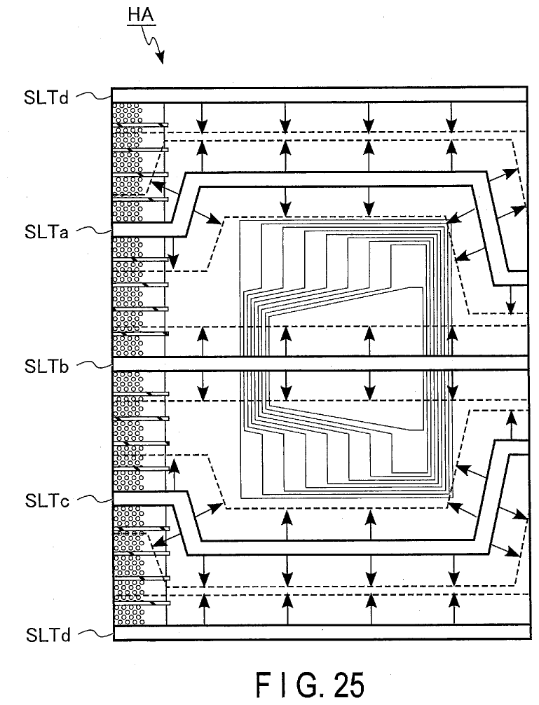

FIG. 25 shows an outline of a development process of replacement processing in the comparative example of the fourth embodiment. Arrangements of a plurality of slits SLT and hookup parts HP in the comparative example of the fourth embodiment are similar to those in the second embodiment. In the replacement processing, after a plurality of sacrificial members are stacked, slits SLTa, SLTb, SLTc, and SLTd that divide the sacrificial members are formed as shown in FIG. 25. Then, by wet etching via the slits SLTa, SLTb, SLTc, and SLTd, the stacked sacrificial members are selectively removed.

A processing time for the wet etching in the replacement processing is set based on a distance between the slits SLT sandwiching a layer stack including the sacrificial members. Specifically, in a case where the slits SLTa and SLTc have a crank shape within the hookup area HA, for example, each of a distance between adjacent slits SLTa and SLTb and a distance between adjacent slits SLTb and SLTc is locally long. The longer the distance between the adjacent slits SLT, the longer the time to remove the sacrificial member at a portion away from the slits SLT. Thus, in the comparative example of the fourth embodiment, the wet etching processing time is set based on the locally long distance between the slits SLT within the hookup area HA.

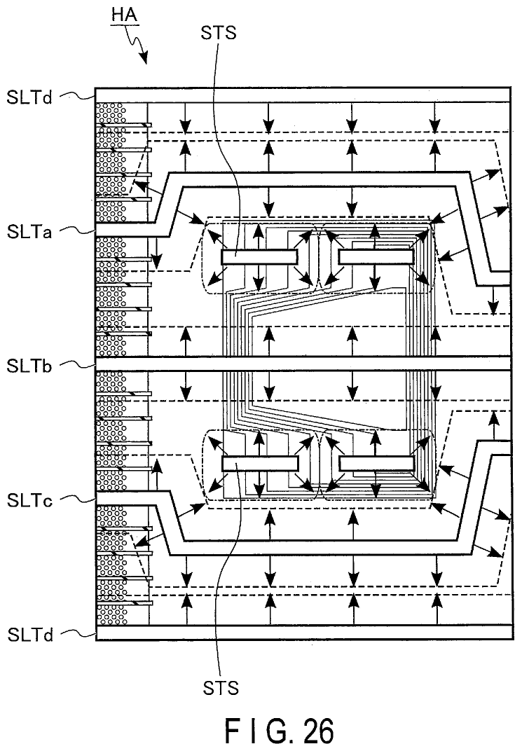

In contrast, the semiconductor memory device 1 according to the fourth embodiment includes a plurality of slits STS in the hookup area HA. FIG. 26 shows an outline of a development process of replacement processing in the fourth embodiment, showing an area similar to that shown in FIG. 25. As shown in FIG. 26, in the semiconductor memory device 1 according to the fourth embodiment, the slits STS are disposed in a portion where a distance between adjacent slits SLT is large in the hookup area HA.

During wet etching, a plurality of stacked sacrificial members are removed through the slits SLT and also through the slits STS. Namely, the slits STS can cause removal of the sacrificial members in the portion where a distance between adjacent slits SLT is large to progress during the wet etching. In other words, the slits STS can shorten a distance for replacing the sacrificial members with the word lines WL.

As a result, the semiconductor memory device 1 according to the fourth embodiment can shorten a processing time for the wet etching along with the replacement processing as compared to that in the second embodiment. Namely, the semiconductor memory device 1 according to the fourth embodiment can improve a throughput relating to the replacement processing, and thus can lower the manufacturing costs of the semiconductor memory device 1.

### [4-3] Modification of Fourth Embodiment

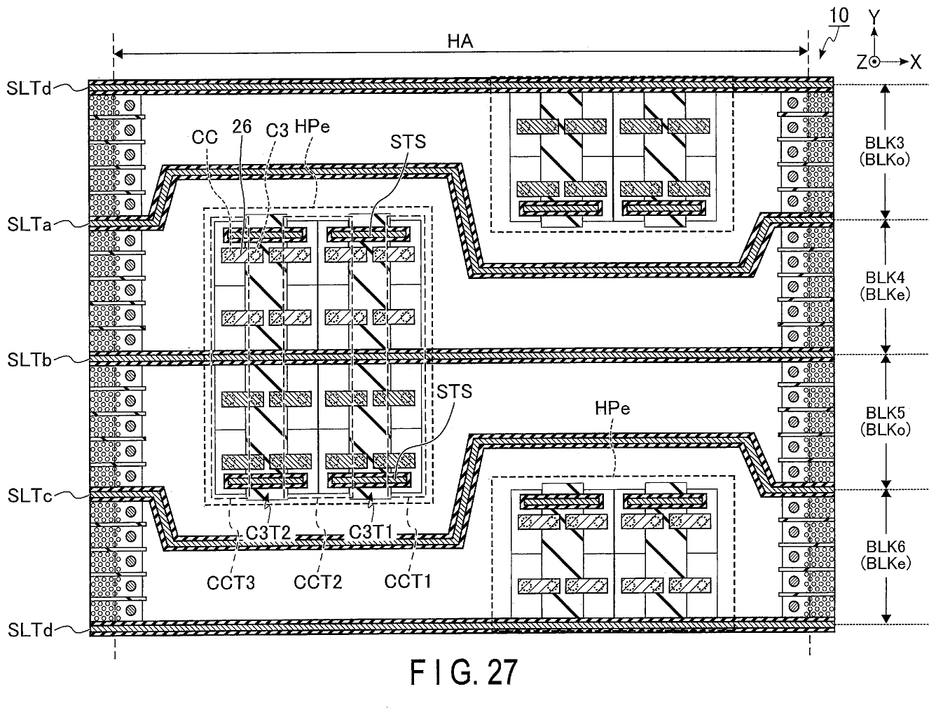

The slits STS described in the fourth embodiment may be added to the semiconductor memory device 1 according to the third embodiment. FIG. 27 shows an example of a detailed planar layout of a memory cell array 10, in a hookup area HA, included in a semiconductor memory device 1 according to a modification of the fourth embodiment.

As shown in FIG. 27, the memory cell array 10 in the modification of the fourth embodiment has a configuration in which a plurality of slits STS are added to the hookup area HA of the memory cell array 10 described in the third embodiment. Slits STS in the modification of the fourth embodiment are disposed so as not to divide a contact area CCT sandwiched between adjacent contact areas C3T within a hookup part HP. The other configurations of the semiconductor memory device 1 according to the modification of the fourth embodiment are the same as those of the third embodiment. Thereby, the semiconductor memory device 1 according to the modification of the fourth embodiment can achieve advantageous effects of a combination of the third and fourth embodiments.

### [5] Fifth Embodiment

A semiconductor memory device 1 according to a fifth embodiment includes a configuration in which the shape of slits SLT intersecting a hookup part HP is different from that of the semiconductor memory device 1 according to the first embodiment. Hereinafter, points in the semiconductor memory device 1 according to the fifth embodiment that are different from the first to fourth embodiments will be described.

### [5-1] Structure of Semiconductor Memory Device 1

(Planar Layout of Memory Cell Array 10 in Hookup Area HA)

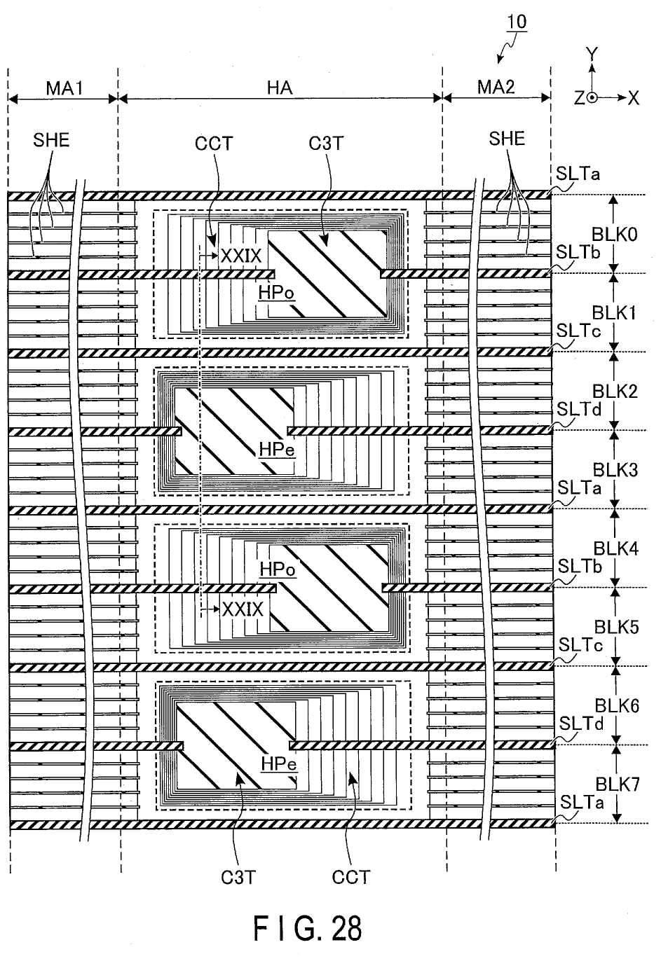

FIG. 28 shows an example of a planar layout of a memory cell array 10, in a hookup area HA, included in the semiconductor memory device 1 according to the fifth embodiment, showing a region similar to that shown in FIG. 4 described in the first embodiment.

As shown in FIG. 28, the memory cell array 10 in the fifth embodiment has a configuration in which the slits SLT intersecting the contact areas C3T are divided in the hookup area HA of the memory cell array 10 described in the first embodiment. Specifically, the slit SLTb intersecting the hookup part HPo is divided in the contact area C3T within the hookup part HPo. Similarly, the slit SLTd intersecting the hookup part HPe is divided in the contact area C3T within the hookup part HPe. Each of the slits SLTb and SLTd in the fifth embodiment may separate and insulate at least stacked interconnects of adjacent blocks BLK.

(Cross-Sectional Structure of Memory Cell Array 10 in Hookup Area HA)

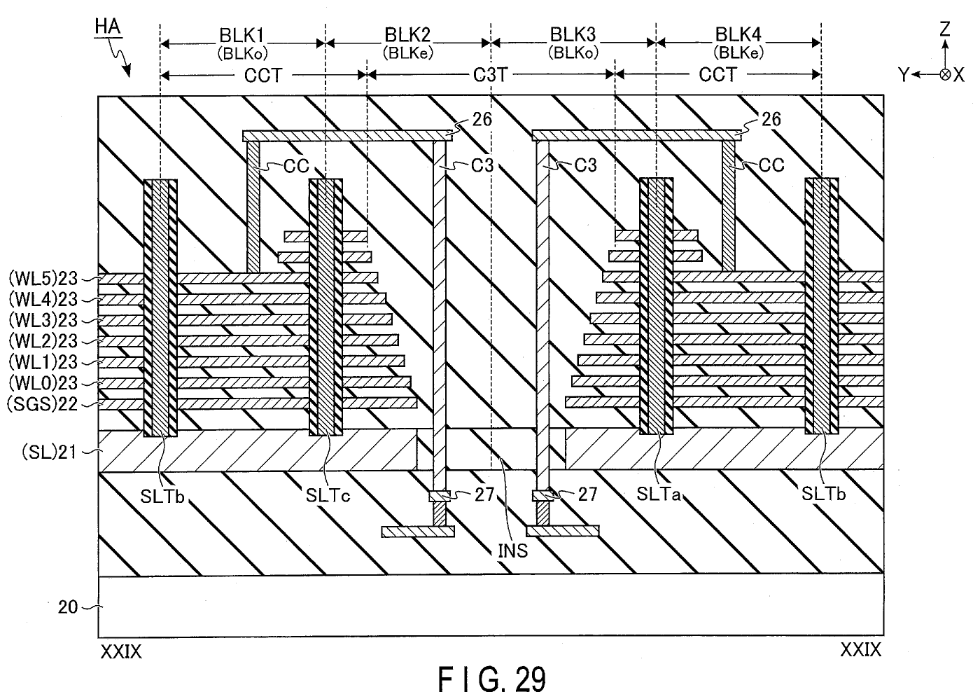

FIG. 29 shows an example of a cross-sectional structure of the memory cell array 10, in the hookup area HA, included in the semiconductor memory device 1 according to the fifth embodiment, showing a cross section, taken along line XXIX-XXIX in FIG. 28. Specifically, FIG. 29 shows a cross section including four blocks BLK1 to BLK4 and along the Y direction.

As shown in FIG. 29, the slit SLTd is omitted in the contact area C3T of the memory cell array 10 in the fifth embodiment. Similarly, the slit SLTb is omitted in the contact area C3T, illustration of which is omitted. Then, the contact area C3T, including the portions where the slits SLTb and SLTd are omitted, has a structure in which an insulator is embedded therein. Thus, in the fifth embodiment, a stacked structure of insulating layers and conductive layers is not provided in the portions where the slits SLTb and SLTd are omitted. The other configurations of the semiconductor memory device 1 according to the fifth embodiment are the same as those of the first embodiment.

### [5-2] Advantageous Effects of Fifth Embodiment

According to the above-described semiconductor memory device 1 according to the fifth embodiment, the yield of the semiconductor memory device 1 can be improved. Hereinafter, details of advantageous effects in the semiconductor memory device 1 according to the fifth embodiment will be described using a comparative example.

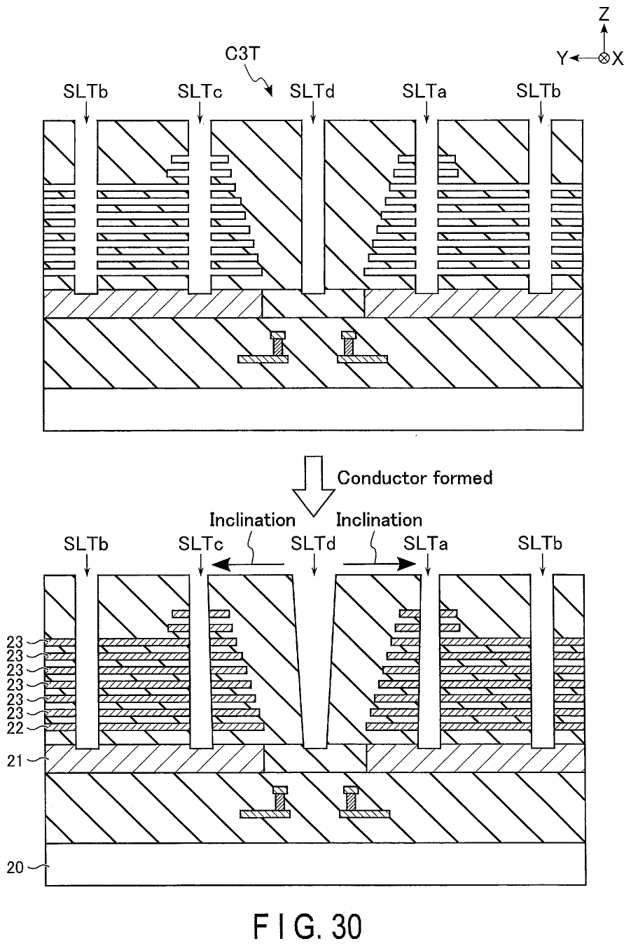

FIG. 30 shows an example of a development process of replacement processing in the comparative example of the fifth embodiment, showing a cross section of an area corresponding to FIG. 29. The upper side of FIG. 30 corresponds to a state in which, after a plurality of slits SLT are formed, sacrificial members SM are removed through the slits SLT, in the replacement processing. Afterwards, as shown on the lower side of FIG. 30, when a conductor is formed by, for example, CVD (Chemical Vapor Deposition), spaces from which the sacrificial members SM are removed are filled with the conductor.

At this time, at portions of the slits SLTb and SLTd overlapping the contact area C3T, a symmetry of a layer stack is disturbed. Specifically, in a structure between the slits SLTd and SLTc, an area in which the sacrificial members SM are removed on the slit SLTc side is filled with the conductor. On the other hand, on the slit SLTd side, the conductor is formed on a side surface of the slit SLTd. Similarly, in a structure between the slits SLTd and SLTa, an area in which the sacrificial members SM are removed on the slit SLTa side is filled with the conductor. On the other hand, on the slit SLTd side, the conductor is formed on a side surface of the slit SLTd.

In this way, in a structure sandwiched between two slits SLT, an asymmetry in the conductor to be formed can occur between two surfaces contacting the slits SLT. Such an asymmetry can cause inclination of the layer stack in directions of illustrated arrows due to, for example, an effect of contraction of the structure along with the metal formation, etc. The inclination of the structure can cause defects in a case where high aspect ratio processing is performed to form stacked interconnects.

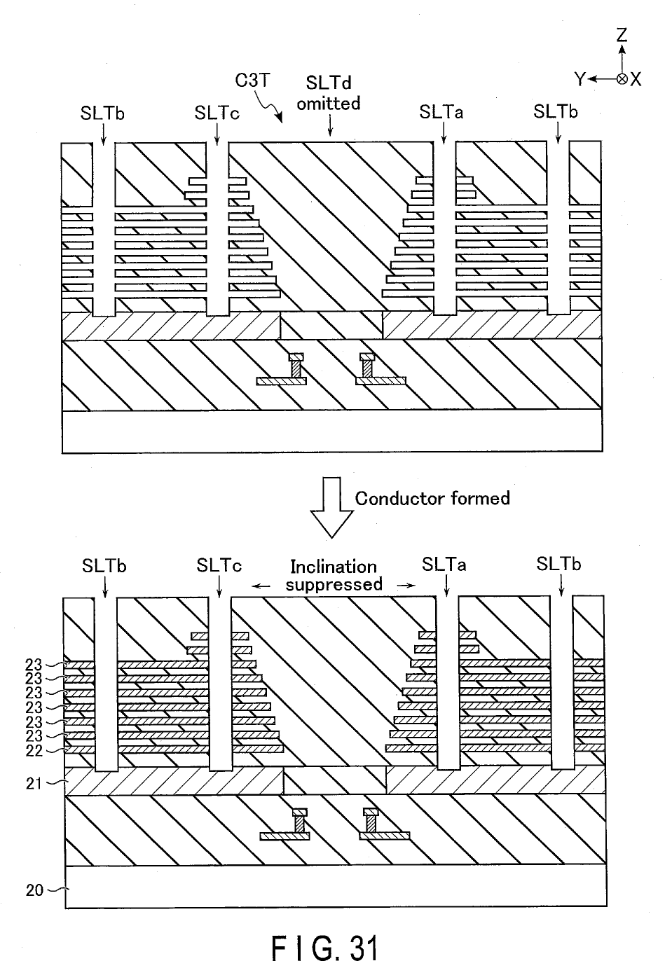

In contrast, the semiconductor memory device 1 according to the fifth embodiment has a structure in which a portion of the slit SLT that overlaps the contact area C3T is omitted. FIG. 31 shows an example of a development process of replacement processing in the fifth embodiment, showing a similar situation to that shown in FIG. 30. As shown on the upper side of FIG. 31, in the fifth embodiment, the slit SLTd overlapping the contact area C3T is omitted. Afterwards, as shown on the lower side of FIG. 31, when a conductor is formed by, for example, CVD, etc., spaces from which the sacrificial members SM are removed are filled with the conductor.

In the semiconductor memory device 1 according to the fifth embodiment, the asymmetry of the structure is resolved by omission of the slit SLTd. Specifically, in a structure between the slits SLTc and SLTa, areas in which the sacrificial members SM are removed are filled with the conductor on both the slit SLTc side and the slit SLTa side. In addition, an aspect ratio of the structure between the slits SLTc and SLTa is lower than that in the comparative example of the fifth embodiment.

As a result, the semiconductor memory device 1 according to the fifth embodiment can suppress occurrence of the inclination of the layer stack in the contact area C3T in the replacement processing. Consequently, the semiconductor memory device 1 according to the fifth embodiment can suppress occurrence of defects along with the replacement processing, thereby improving the yield of the semiconductor memory device 1.

In addition, in the semiconductor memory device 1 according to the fifth embodiment, the contact C3 may be disposed at the portions where the slits SLTb and SLTd are omitted. Thus, in the semiconductor memory device 1 according to the fifth embodiment, the degree of freedom in layout of the contacts C3 in the contact area C3T can be improved, thereby suppressing the difficulty of designing the semiconductor memory device 1.

### [5-3] Modification of Fifth Embodiment

The semiconductor memory device 1 according to the fifth embodiment can be modified in various ways. Hereinafter, points in the first, second, third, and fourth modifications of the fifth embodiment that are different from the fifth embodiment will be described in order.

### First Modification of Fifth Embodiment

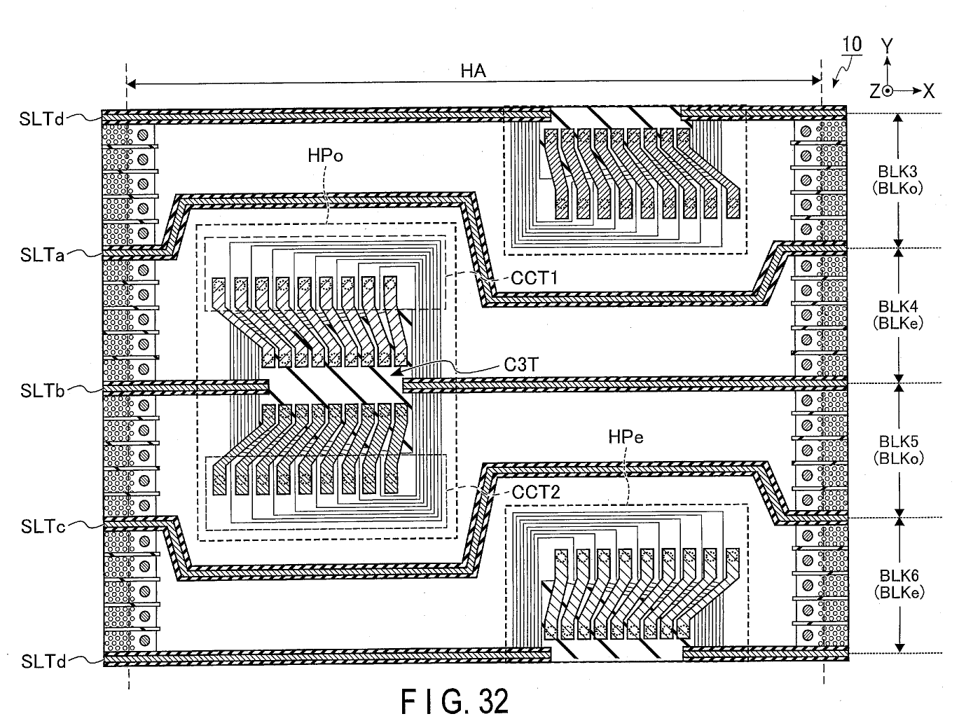

A semiconductor memory device 1 according to the first modification of the fifth embodiment corresponds to a combination of the fifth embodiment and the second embodiment. FIG. 32 shows an example of a detailed planar layout of a memory cell array 10, in a hookup area HA, included in the semiconductor memory device 1 according to the first modification of the fifth embodiment.

As shown in FIG. 32, the memory cell array 10 in the first modification of the fifth embodiment has a configuration in which the slit SLT overlapping the contact area C3T is divided in the hookup area HA of the memory cell array 10 described in the second embodiment in the same manner as in the fifth embodiment. Thus, the semiconductor memory device 1 according to the first modification of the fifth embodiment can achieve advantageous effects of a combination of the second and fifth embodiments.

Note that if the slits SLTa and SLTc have a crank shape as in the second embodiment, the asymmetry of the layer stack increases in an area corresponding to the crank shape. Thus, the advantageous effects obtained by applying the fifth embodiment to the semiconductor memory device 1 according to the second embodiment can be greater than that of the first embodiment.

### Second Modification of Fifth Embodiment

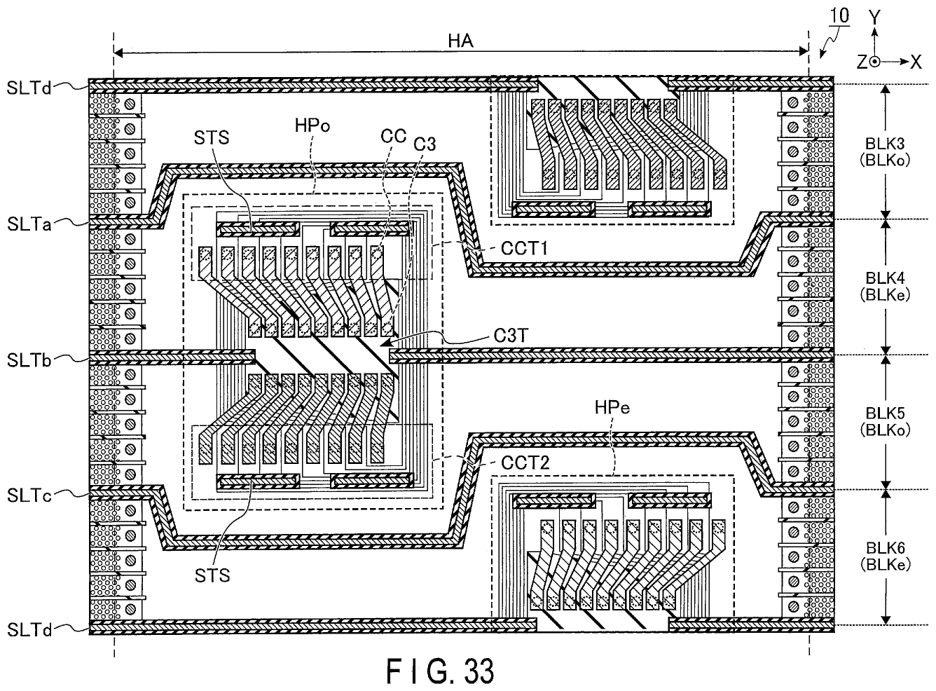

A semiconductor memory device 1 according to the second modification of the fifth embodiment corresponds to a combination of the fifth and fourth embodiments. FIG. 33 shows an example of a detailed planar layout of a memory cell array 10, in a hookup area HA, included in the semiconductor memory device 1 according to the second modification of the fifth embodiment.

As shown in FIG. 33, the memory cell array 10 in the second modification of the fifth embodiment has a configuration in which the slit SLT overlapping the contact area C3T is divided in the hookup area HA of the memory cell array 10 described in the fourth embodiment. Specifically, the slit SLTb intersecting the hookup part HPo is divided in the contact area C3T within the hookup part HPo. Similarly, the slit SLTd intersecting the hookup part HPe is divided in the contact area C3T within the hookup part HPe. Each of the slits SLTb and SLTd in the fifth embodiment may separate at least stacked interconnects of adjacent blocks BLK. Thus, the semiconductor memory device 1 according to the second modification of the fifth embodiment can achieve advantageous effects of a combination of the fourth and fifth embodiments.

### Third Modification of Fifth Embodiment

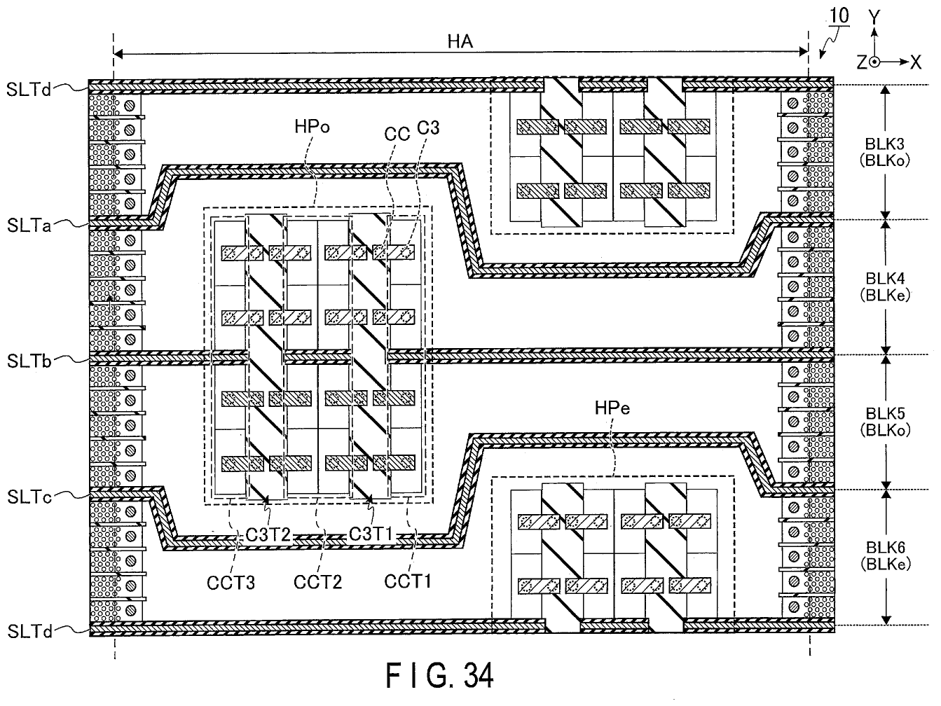

A semiconductor memory device 1 according to the third modification of the fifth embodiment corresponds to a combination of the fifth and third embodiments. FIG. 34 shows an example of a detailed planar layout of a memory cell array 10, in a hookup area HA, included in the semiconductor memory device 1 according to the third modification of the fifth embodiment.

As shown in FIG. 34, the memory cell array 10 in the third modification of the fifth embodiment has a configuration in which the slit SLT overlapping the contact areas C3T1 and C3T2 is divided in the hookup area HA of the memory cell array 10 described in the third embodiment in the same manner as in the first modification of the fifth embodiment. Thus, the semiconductor memory device 1 according to the third modification of the fifth embodiment can achieve advantageous effects of a combination of the third and fifth embodiments.

### Fourth Modification of Fifth Embodiment

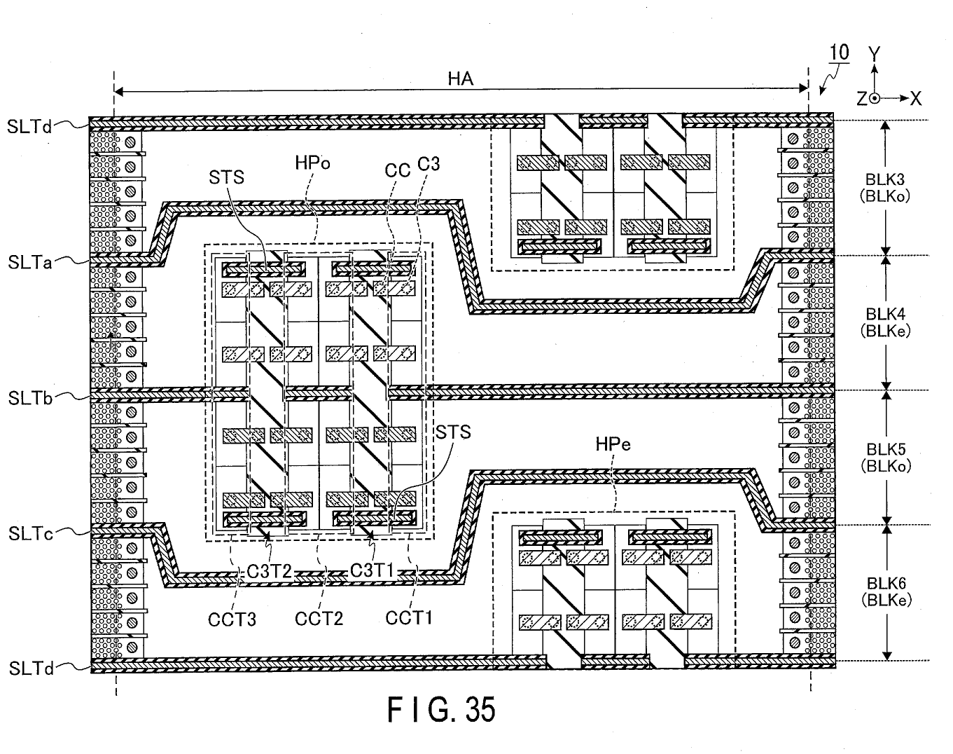

A semiconductor memory device 1 according to the fourth modification of the fifth embodiment corresponds to a combination of the fifth embodiment and the modification of the fourth embodiment. FIG. 35 shows an example of a detailed planar layout of a memory cell array 10, in a hookup area HA, included in the semiconductor memory device 1 according to the fourth modification of the fifth embodiment.

As shown in FIG. 35, the memory cell array 10 in the fourth modification of the fifth embodiment has a configuration in which the slit SLT overlapping the contact areas C3T1 and C3T2 is divided in the hookup area HA of the memory cell array 10 described in the modification of the fourth embodiment. Thus, the semiconductor memory device 1 according to the fourth modification of the fifth embodiment can achieve advantageous effects of a combination of the modification of the fourth embodiment and the fifth embodiment.

### [6] Sixth Embodiment

A semiconductor memory device 1 according to a sixth embodiment has a stepped structure in a hookup part HP that is different from that of the semiconductor memory device 1 according to the first embodiment. Hereinafter, points in the semiconductor memory device 1 according to the sixth embodiment that are different from the first embodiment will be described.

### [6-1] Structure of Semiconductor Memory Device 1

(Planar Layout of Memory Cell Array 10 in Hookup Area HA)

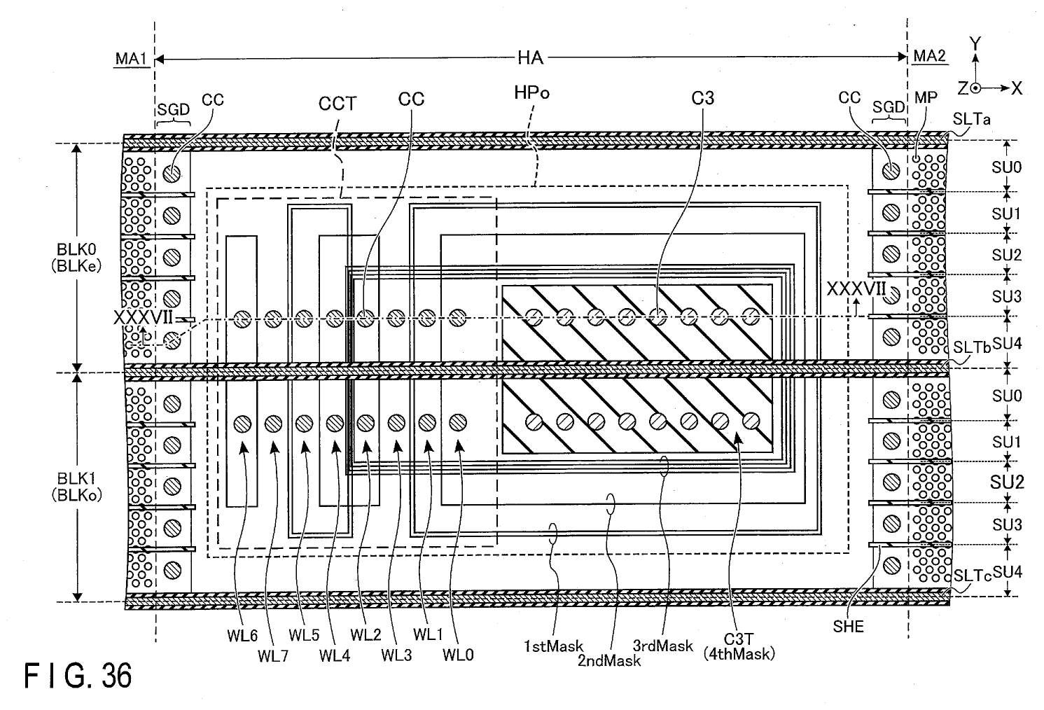

FIG. 36 shows an example of a planar layout of a memory cell array 10, in a hookup area HA, included in the semiconductor memory device 1 according to the sixth embodiment, showing a region similar to that shown in FIG. 8 described in the first embodiment. Although not shown, in the hookup area HA in the sixth embodiment, stacked interconnects and contacts provided in a hookup part HPo and those provided in a hookup part HPe are, for example, disposed in a symmetrical structure in the X direction, in the same manner as in the first embodiment. Namely, since the layouts of the hookup parts HPo and HPe are similar, the hookup part HPo will be described below. Note that in the present embodiment, illustration of a configuration relating to coupling of a contact to the select gate line SGS is omitted to simplify the explanation.

As shown in FIG. 36, the memory cell array 10 in the sixth embodiment has a configuration in which the arrangement of the terraced portions of a plurality of word lines WL arranged in the X direction is different in the hookup area HA of the memory cell array 10 described in the first embodiment. Specifically, the respective terraced portions of the word lines WL6, WL7, WL5, WL4, WL2, WL3, WL1, and WL0 are arranged in this order in a direction from the contact area CCT toward the contact area C3T.

In addition, FIG. 36 shows a region of a mask used for formation of the above-described stepped structure. Specifically, areas respectively surrounded by a rectangle of double solid lines correspond to opening portions of a first mask (1stMask). The opening portions of 1stMask include a rectangular area including the terraced portions of the word lines WL4 and WL5 and a rectangular area including the terraced portions of the word lines WL0 and WL1 and the contact area C3T. Areas respectively surrounded by a rectangle of a solid line correspond to opening portions of a second mask (2ndMask). The opening portions of 2ndMask include a rectangular area including the terraced portion of the word line WL6, a rectangular area including the terraced portions of the word lines WL2 and WL4, and a rectangular area including the terraced portion of the word line WL0 and the contact area C3T. An area surrounded by a rectangle of a quadruple solid line corresponds to an opening portion of a third mask (3rdMask). The opening portion of 3rdMask includes a rectangular area including the terraced portions of the word lines WL0 to WL3 and the contact area C3T. Then, the contact area C3T corresponds to an opening portion of a fourth mask (4thMask).

(Cross-Sectional Structure of Memory Cell Array 10 in Hookup Area HA)

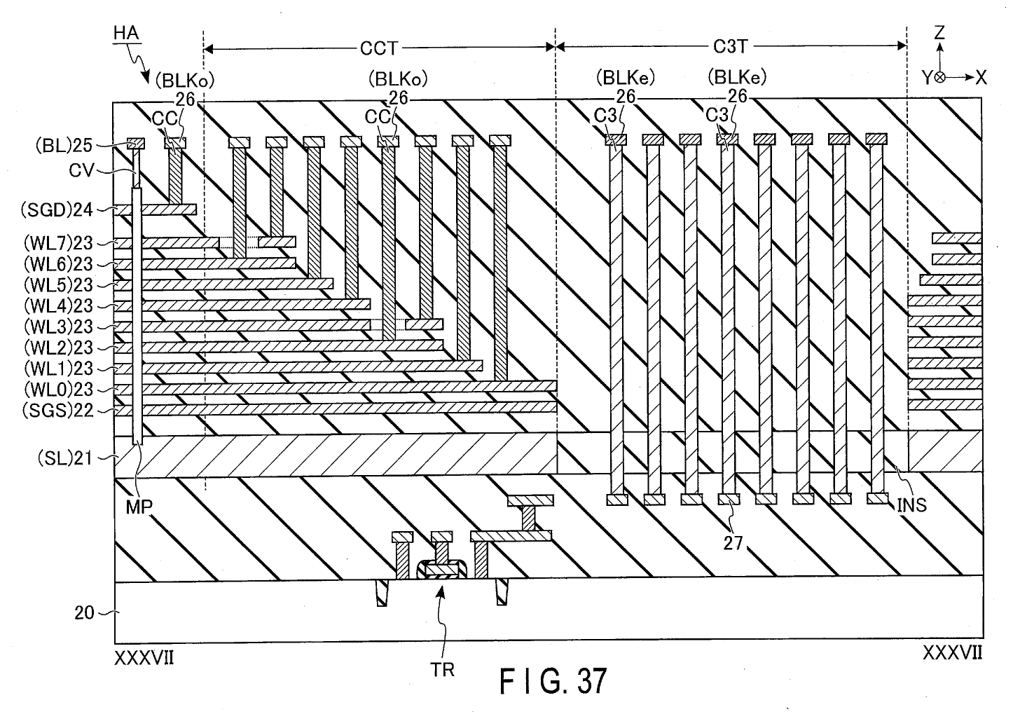

FIG. 37 is a cross-sectional view, taken along line XXXVII-XXXVII of FIG. 36, which shows an example of a cross-sectional structure of the memory cell array 10, in the hookup area HA, included in the semiconductor memory device 1 according to the sixth embodiment, showing a region similar to that shown in FIG. 10 described in the first embodiment.

As shown in FIG. 37, the cross-sectional structure of the memory cell array 10 in the hookup area HA in the sixth embodiment is such that a stepped structure of the word lines WL is different from that in the first embodiment. Each of the terraced portion of the word line WL7 and the terraced portion of the word line WL3 is provided discontinuously on the cross section. However, as shown in FIG. 36, each of the terraced portion of the word line WL7 and the terraced portion of the word line WL3 has a portion provided continuously between the adjacent slits SLT. Thus, the row decoder module 15 can apply a voltage to the word line WL7 via the contact CC coupled to the terraced portion of the word line WL7, and apply a voltage to the word line WL3 via the contact CC coupled to the terraced portion of the word line WL3. The other configurations of the semiconductor memory device 1 according to the sixth embodiment are the same as those of the first embodiment.

### [6-2] Manufacturing Method of Semiconductor Memory Device 1

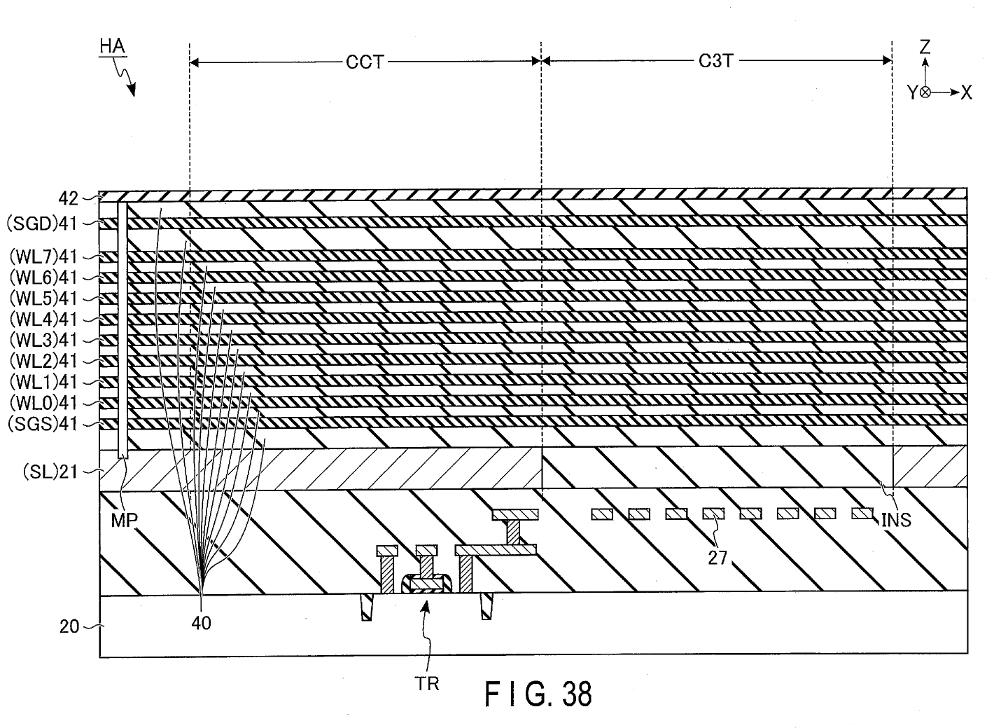

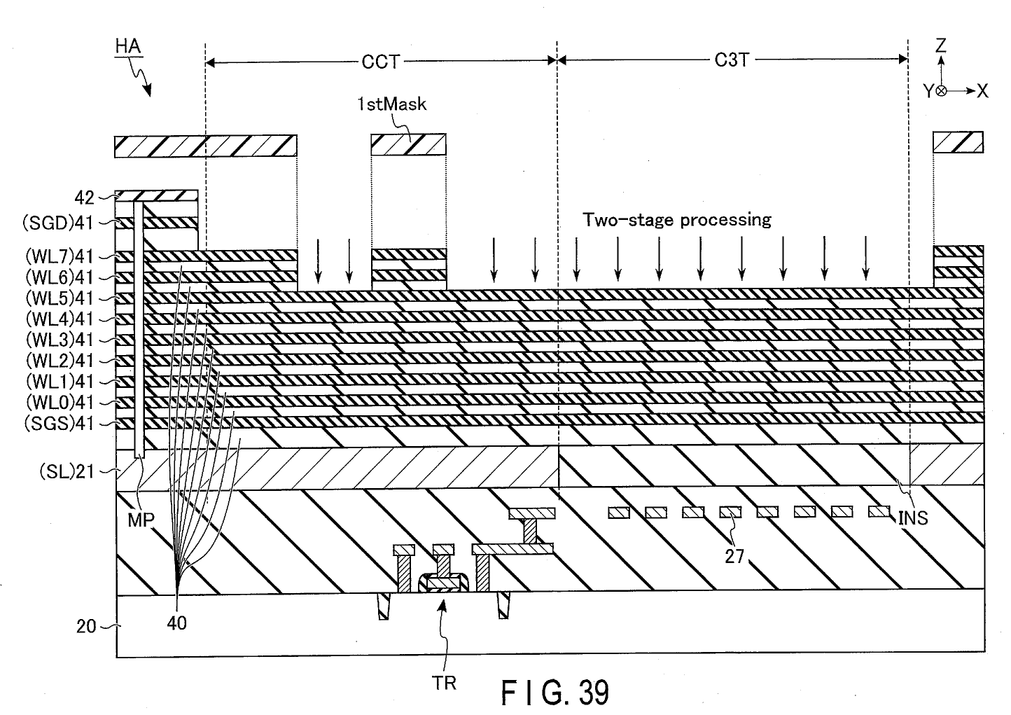

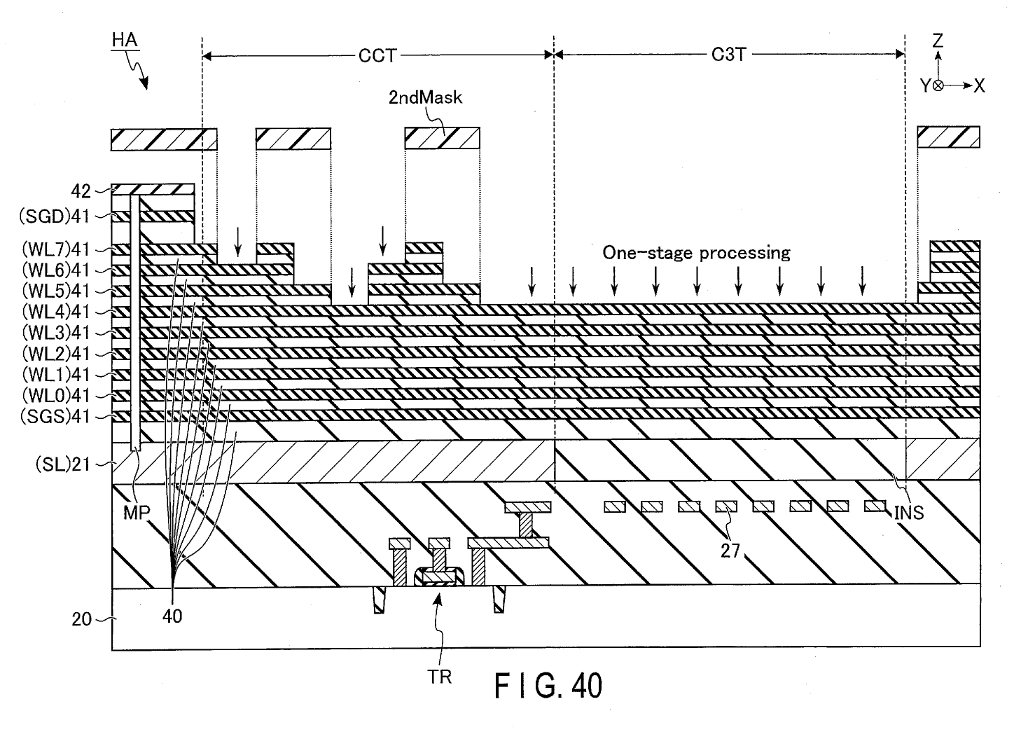

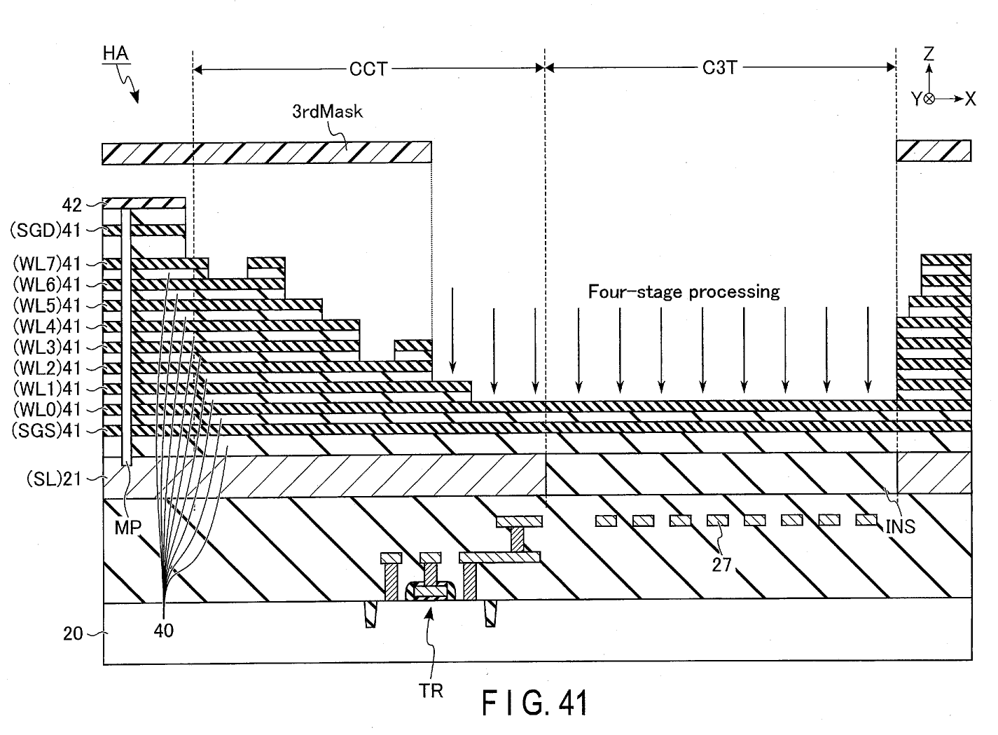

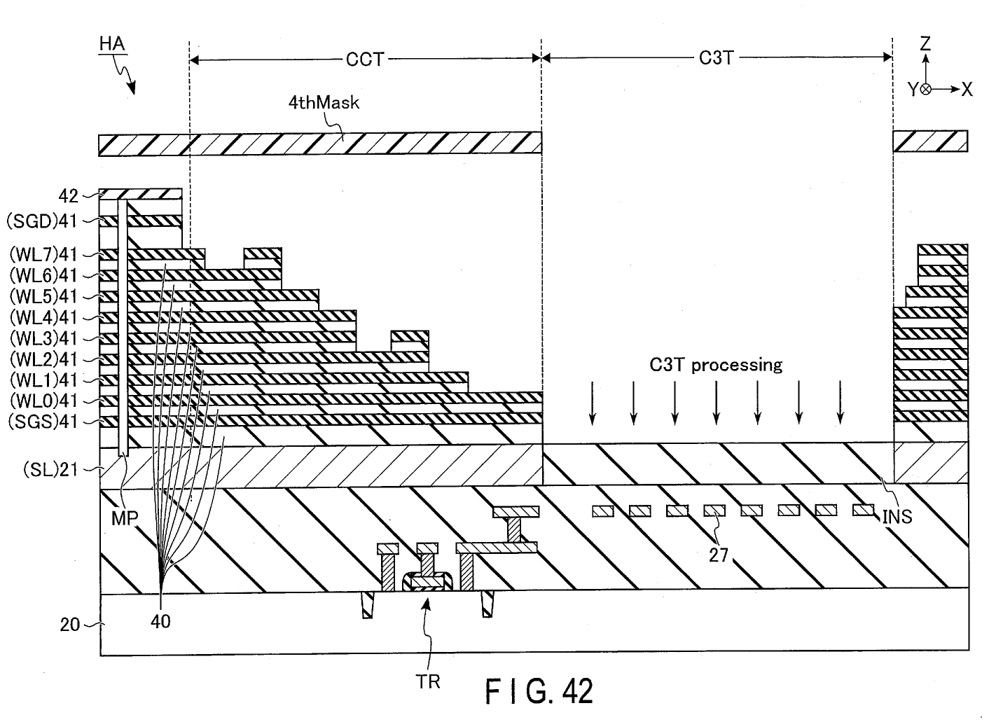

Hereinafter, an example of a method of forming the stepped structure of the memory cell array 10, in the hookup area HA, included in the semiconductor memory device 1 according to the sixth embodiment will be described with reference to FIGS. 38 to 42. Each of FIGS. 38 to 42 shows an example of a cross-sectional structure of the memory cell array 10 under manufacturing of the semiconductor memory device 1 according to the sixth embodiment, showing a region similar to that shown in FIG. 37. A mask illustrated in the following drawings supplementarily shows a processing area of etching. Etching used in staircase shaping has an anisotropy, and is, for example, reactive ion etching (RIE).

First, as shown in FIG. 38, sacrificial members 41 are stacked, and a memory pillar MP is formed. Briefly speaking, before the sacrificial members 41 are stacked, part of a conductive layer 21 corresponding to a source line SL is removed, and an insulating layer INS is formed. Then, insulating layers 40 and the sacrificial members 41 are provided in an alternating manner on the conductive layer 21. The number of layers of the sacrificial members 41 to be provided corresponds to, for example, the total number of layers of the select gate lines SGS and SGD and word lines WL, and the word lines WL may include a dummy word line layer not used as information storage. Then, a memory hole penetrating a plurality of insulating layers 40 and a plurality of sacrificial members 41 is formed, and the memory pillar MP is formed inside the memory hole. After that, for example, a passivation film 42 is provided on the uppermost insulating layer 40. Afterwards, although illustration is omitted, the uppermost sacrificial member 41 is first processed in accordance with the shape of the select gate line SGD.

Next, as shown in FIG. 39, by etching using the first mask (1stMask), two sets of the insulating layer 40 and the sacrificial member 41 are removed (two-stage processing). Then, as shown in FIG. 40, by etching using the second mask (2ndMask), one set of the insulating layer 40 and the sacrificial member 41 is removed (one-stage processing). After then, as shown in FIG. 41, by etching using the third mask (3rdMask), four sets of the insulating layer 40 and the sacrificial member 41 are removed (four-stage processing). Thereby, eight terraced portions respectively corresponding to the eight word lines WL, as shown in FIG. 36, are formed.

Next, as shown in FIG. 42, by etching using the fourth mask (4thMask), for example, two sets of the insulating layer 40 and the sacrificial member 41 are removed. Thereby, the sacrificial members 41 of a portion corresponding to the contact area C3T are removed. In other words, in the contact area C3T, a structure in which the sacrificial members 41 above the insulating layer INS are removed is formed.

Afterwards, level differences due to the stepped structure of the memory cell array 10 are filled by an insulator, and planarization of an upper surface of the structure formed on the wafer is executed. Then, slits SLT that divide the stacked sacrificial members 41 are formed, and replacement processing using the slits SLT is executed. Briefly described, the sacrificial members 41 are selectively removed through the slits SLT, and a conductor is formed in a space from which the sacrificial members 41 are removed. As a result, a stepped structure of stacked interconnects as shown in FIG. 37 is formed.

### [6-3] Advantageous Effects of Sixth Embodiment

Advantageous effects of the sixth embodiment will be described in comparison with the first embodiment. In the semiconductor memory device 1 according to the first embodiment, for example, individual masks are prepared to form eight types of terraced portions, and eight types of masks in total are used. Thus, in the semiconductor memory device 1 according to the first embodiment, at least nine masks including the eight masks used to form the terraced portions and one mask used to form the contact area C3T are used to form the stepped structure.

On the other hand, the method of manufacturing the semiconductor memory device 1 according to the sixth embodiment uses five masks to form eight types of terraced portions and the contact area C3T. Thus, the method of manufacturing the semiconductor memory device 1 according to the sixth embodiment can reduce the number of masks to be used to form a stepped structure as compared to the first embodiment. Reducing the number of masks can lead to saving the costs related to production of the masks, and further reducing manufacturing processes of the semiconductor memory device 1. Accordingly, the semiconductor memory device 1 according to the sixth embodiment can suppress the manufacturing costs as compared to the first embodiment.

### [6-4] Modification of Sixth Embodiment

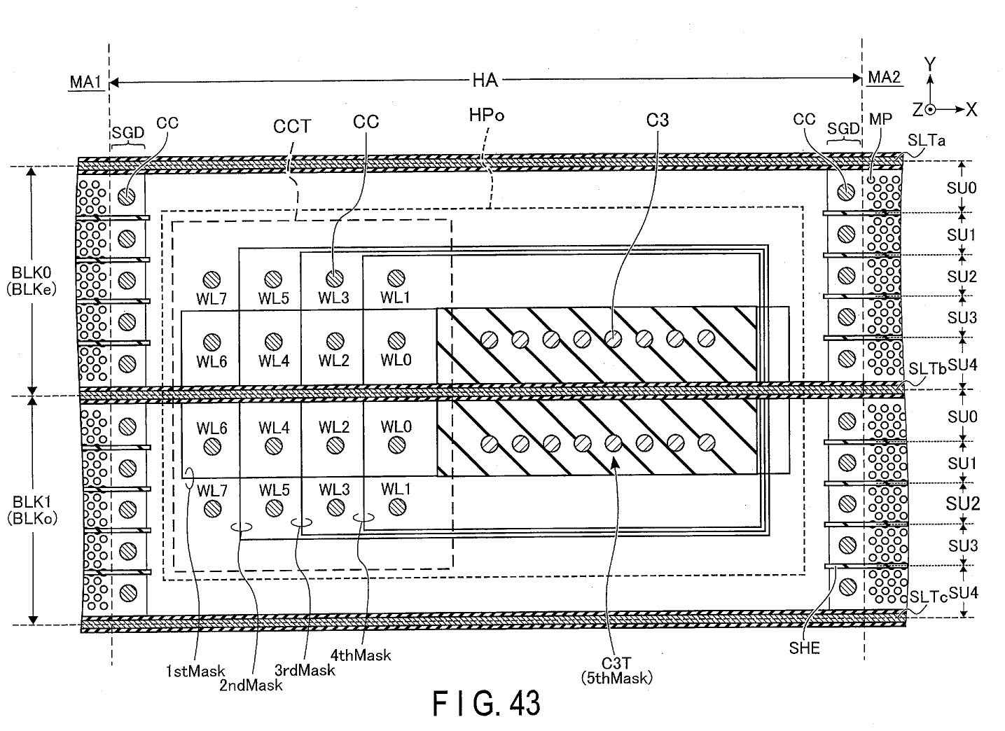

The semiconductor memory device 1 according to the sixth embodiment can be modified in various ways. For example, a multi-row stepped structure may be formed in the hookup area HA of the memory cell array 10 included in the semiconductor memory device 1 according to the sixth embodiment. FIG. 43 shows an example of a planar layout of the memory cell array 10, in the hookup area HA, included in the semiconductor memory device 1 according to the modification of the sixth embodiment, showing a region similar to that shown in FIG. 36 described in the sixth embodiment. Note that it is also assumed herein that stacked interconnects and contacts provided in the hookup part HPo and those provided in the hookup part HPe are, for example, disposed in a symmetric structure in the X direction, and the hookup part HPo will be described below.

As shown in FIG. 43, the respective terraced portions of the word lines WL0, WL2, WL4, and WL6 corresponding to the block BLK0 (BLKe) are arranged in the X direction. Above them on the paper, the respective terraced portions of the word lines WL1, WL3, WL5, and WL7 corresponding to the block BLK0 (BLKe) are arranged in the X direction. In other words, in an area of the hookup part HPo above the slit SLTb on the paper, a two-row stepped structure of stacked interconnects is provided. Then, a configuration of the hookup part HPo below the slit SLTb, i.e., the block BLKo, is, for example, similar to a configuration of the hookup part HPo above the slit SLTb that is inverted with the slit SLTb as a symmetrical axis.

In addition, FIG. 43 shows a region of a mask used to form the above-described stepped structure. Specifically, the opening portion of the first mask (1stMask) includes a rectangular area including the terraced portions of the word lines WL0, WL2, WL4, and WL6 of the blocks BLK adjacent via the slit SLTb and a rectangular area including the contact area C3T. The opening portion of the second mask (2ndMask) includes a rectangular area including the terraced portions of the word lines WL0 to WL5 of the blocks BLK adjacent via the slit SLTb and the rectangular area including the contact area C3T. The opening portion of the third mask (3rdMask) includes a rectangular area including the terraced portions of the word lines WL0 to WL3 of the blocks BLK adjacent via the slit SLTb and the rectangular area including the contact area C3T. The opening portion of the fourth mask (4thMask) includes a rectangular area including the terraced portions of the word lines WL0 and WL1 of the blocks BLK adjacent via the slit SLTb and the rectangular area including the contact area C3T. Then, the contact area C3T corresponds to an opening portion of a fifth mask (5thMask).

As described above, the method of manufacturing the semiconductor memory device 1 according to the modification of the sixth embodiment can form a two-row stepped structure for each block BLK by executing staircase shaping similar to that in the sixth embodiment using the above-described five masks. In this way, a multi-row stepped structure may be formed in the hookup area HA in accordance with arrangements of the opening portions of the masks. Also in a case where a multi-row stepped structure is formed, the number of masks to be used and the manufacturing processes can be reduced and the manufacturing costs can be suppressed as in the sixth embodiment. Then, in a case where a multi-row stepped structure is formed in the hookup area HA, the width of the contact area CCT in the X direction can be suppressed.

Note that the stepped structure formed in the hookup area HA is not limited to the above-described structure. For example, the number of steps to be formed and the arrangement of terraced portions can be freely designed. The sixth embodiment may be combined with the fifth embodiment. For example, the slit SLTb shown in FIGS. 36 and 43 may be divided at a portion intersecting the contact area C3T. In this case, the semiconductor memory device 1 can achieve advantageous effects of a combination of the fifth and sixth embodiments.

### [7] Others

In the above-described embodiments, other contact may be provided between any contact CC and conductive layer 26 and between any contact C3 and conductive layer 26. In other words, for example, any conductive layer 23 and conductive layer 26 and any conductive layer 26 and conductive layer 27 may be coupled by a plurality of contacts coupled in the Z direction. In a case where a plurality of contacts are coupled in the Z direction, a conductive layer may be inserted into a coupled portion.

In the drawings used for explanation in the above-described embodiments, the memory pillars MP are illustrated as having the same diameter in the Z direction, but are not limited thereto. For example, the memory pillars MP may have a tapered or reverse-tapered shape, or may have a shape having a fat middle portion (bowing shape). Similarly, each of the slits SLT, SHE, and STS may have a tapered or reverse-tapered shape, or may have a bowing shape. In addition, in the embodiments, a case is illustrated where each of the memory pillars MP and the contacts CC and C3 has a circular cross section. However, the cross section of each component may be ellipsoidal, or indeed any shape.

In the above-described embodiments, various types of insulators may be adopted to fill the slits SLT, SHE, and STS. In this case, for example, a contact corresponding to the source line SL (conductive layer 21) is provided in the hookup area HA. In the present specification, the positions of the slits SLT and STS are specified based on, for example, the positions of the contacts LI. In addition, in a case where the slits SLT and STS are formed by an insulator, the positions of the slits SLT and STS may be specified by a seam in the slits SLT and STS or materials that remain in the slits SLT and STS at the time of the replacement processing.

In the above-described embodiments, a case where the memory cell array 10 has one hookup area HA is exemplified, but the configuration is not limited thereto. In the memory cell array 10, at least one hookup area HA may be provided, and a plurality of hookup areas HA may be provided. The hookup area HA may be disposed to divide the memory area MA, or to be adjacent to the memory area MA at an end part. In a case where only one hookup area HA is provided, the hookup area HA is preferably inserted at a middle portion of the memory areas MA as in the first embodiment. Thus, the semiconductor memory device 1 can suppress a delay in voltage change at an end part of a word line WL that can occur based on wiring resistance of the word line WL.

In the above-described embodiments, the hookup part HPo and the hookup part HPe are preferably provided in a symmetric structure in the X direction, for example. This is because the symmetric structure can make the layout and process of each circuit provided in the hookup area HA easier than the asymmetric structure. For example, the semiconductor memory device 1 according to the first embodiment has the hookup parts HPo and HPe in a symmetric structure so as to make the step area (contact area CCT) and the penetration area (contact area C3T) close to each other, thereby facilitating the layout of interconnects of an upper layer of the memory cell array 10. In the semiconductor memory device 1 according to the second embodiment or the third embodiment, interconnects of lower and upper layers of the memory cell array 10 are coupled using penetrating contacts of the contact area C3T within the same hookup area HA. Thus, when considering the layout and process in a logic circuit of the lower layer, the hookup parts HPo and HPe preferably have a symmetric structure. This advantageous effect does not depend on the arrangement of the hookup area HA. A similar advantageous effect can be obtained in a case where the hookup area HA is disposed at an end part of the memory cell array 10, for example.

In the third embodiment, a case where the word lines WL0 to WL7 are provided in a two-row staircase pattern in the hookup part HP is exemplified, but the configuration is not limited thereto. In the hookup part HP, a staircase of three rows or more in the Y direction may be formed. The number of level differences formed at the stacked word lines WL in the X and Y directions can be designed to be any number. In addition, three or more contact areas C3T may be provided in the hookup part HP in the third embodiment. In a case where three contact areas C3T are provided, four contact areas CCT are provided in the hookup part HP.

The term “couple” throughout the specification refers to electrical coupling, and therefore it may include coupling with some other elements interposed therebetween. The expression “electrically coupled” may refer to coupling of components with an insulator interposed therebetween as long as the operation can be conducted in the same manner as when being electrically coupled. A “pillar” refers to a structure provided in a hole formed in the process of manufacturing the semiconductor memory device 1. A “same layer structure” may consist of layers formed at least in the same order.

An “area” may be regarded as a configuration included in the semiconductor substrate 20 throughout the specification. For example, when the semiconductor substrate 20 is defined as including the memory areas MA1 and MA2 and hookup area HA, the memory areas MA1 and MA2 and hookup area HA are respectively associated with different areas above the semiconductor substrate 20. The “height” corresponds to, for example, a distance between a configuration to be measured and the semiconductor substrate 20 in the Z direction. As a criterion of the “height”, a configuration other than the semiconductor substrate 20 may be used. The expression “arranged in the X direction” includes a case where configurations arranged in the X direction are disposed to be offset in the Y direction. Namely, the expression “arranged in the X direction” means that the configurations may be disposed at least along the x direction, and may be disposed in a zigzag pattern.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate including a first area, a second area, and a plurality of block areas, the first area and the second area being arranged in a first direction, each of the block areas being provided to extend in the first direction, and the block areas being arranged in a second direction intersecting the first direction;
a plurality of insulating members provided to extend in the first direction, the insulating members being respectively disposed at boundary portions between the block areas;
a plurality of first conductive layers arranged in a third direction intersecting the first and second directions and provided to be separated from one another, the first conductive layers being divided by the insulating members, and the first conductive layers respectively including terraced portions provided not to overlap an upper first conductive layer for each area in which the second area and any one of the block areas overlap;
a plurality of first pillars provided to penetrate the first conductive layers for each area in which the first area and any one of the block areas overlap;
a plurality of first contacts respectively provided on the terraced portions of the first conductive layers for each of the block areas;
a plurality of second conductive layers respectively coupled to the first contacts above the first conductive layers for each of the block areas; and
a plurality of second contacts provided to extend from a first layer to a second layer and respectively coupled to the second conductive layers for each of the block areas, the first layer being located above the first conductive layers, and the second layer being located between the substrate and the first conductive layers, wherein
the second area includes a plurality of subareas arranged in the second direction, each of the subareas being disposed across a boundary between two different block areas to overlap a part of each of the two different block areas in the second direction,
each of the subareas includes a contact area and an insulating area arranged in the first direction, the contact area including a group of the terraced portions and a group of the first contacts corresponding to two block areas, and the insulating area including a group of the second contacts corresponding to the two block areas,
contact areas of odd-numbered subareas and insulating areas of even-numbered subareas are disposed in an alternating manner in the second direction, and
insulating areas of the odd-numbered subareas and contact areas of the even-numbered subareas are disposed in an alternating manner in the second direction.

2. The device of claim 1, wherein
the block areas include a first block area and a second block area that are adjacent to each other,
the first block area includes a part of one odd-numbered subarea among the odd-numbered subareas,
the second block area includes a part of one even-numbered subarea among the even-numbered subareas,
the first contacts included in the contact area associated with the first block area are electrically coupled to the second contacts included in the insulating area associated with the second block area, respectively, and
the first contacts included in the contact area associated with the second block area are electrically coupled to the second contacts included in the insulating area associated with the first block area, respectively.

3. The device of claim 2, wherein
the second conductive layers coupled to the first conductive layers associated with the first block area via the first contacts and the second conductive layers coupled to the first conductive layers associated with the second block area via the first contacts are arranged in the first direction.

4. The device of claim 1, wherein
an insulating member intersecting one of the subareas among the insulating members is divided at a portion overlapping the insulating area included in the one of the subareas.

5. A semiconductor memory device comprising:
a substrate including a first area, a second area, and a plurality of block areas, the first area and the second area being arranged in a first direction, each of the block areas being provided to extend in the first direction, and the block areas being arranged in a second direction intersecting the first direction;
a plurality of insulating members provided to extend in the first direction, the insulating members being respectively disposed at boundary portions between the block areas;
a plurality of first conductive layers arranged in a third direction intersecting the first and second directions and provided to be separated from one another, the first conductive layers being divided by the insulating members, and the first conductive layers respectively including terraced portions provided not to overlap an upper first conductive layer for each area in which the second area and any one of the block areas overlap;
a plurality of first pillars provided to penetrate the first conductive layers for each area in which the first area and any one of the block areas overlap;
a plurality of first contacts respectively provided on the terraced portions for each of the block areas;
a plurality of second conductive layers respectively coupled to the first contacts above the first conductive layers for each of the block areas; and
a plurality of second contacts provided to extend from a first layer to a second layer and respectively coupled to the second conductive layers for each of the block areas, the first layer being located above the first conductive layers, and the second layer being located between the substrate and the first conductive layers, wherein
the second area includes a plurality of subareas arranged in the second direction, each of the subareas being disposed across a boundary between two different block areas to overlap a part of each of the two different block areas in the second direction,
each of the subareas includes a contact area and an insulating area, the contact area including a group of the terraced portions and a group of the first contacts corresponding to two block areas, and the insulating area including a group of the second contacts corresponding to the two block areas, and
the contact area of an odd-numbered subarea has a structure that is symmetric in the first direction with respect to the contact area of an even-numbered subarea.

6. The device of claim 5, wherein
the terraced portions of the first conductive layers disposed in an area in which the contact area and one block area overlap are arranged in the first direction.

7. The device of claim 6, wherein
the terraced portions of the first conductive layers disposed in the area in which the contact area and the one block area overlap are electrically coupled to the second contacts included in the insulating area of an adjacent subarea in the second direction, respectively.

8. The device of claim 6, wherein
the terraced portions of the first conductive layers disposed in the area in which the contact area and the one block area overlap are electrically coupled to the second contacts included in the insulating area of a same subarea, respectively.

9. The device of claim 5, wherein
the contact area includes a first sub contact area and a second sub contact area arranged in the first direction,
the insulating area includes a first sub insulating area disposed between the first sub contact area and the second sub contact area,
in an area in which the contact area and one block area overlap,
each of the first sub contact area and the second sub contact area includes two different terraced portions arranged in the second direction, the two different terraced portions respectively belonging to two different first conductive layers adjacent in the third direction, and
the second contacts included in the first sub insulating area are electrically coupled to the first contacts included in any one of the first sub contact area and the second sub contact area.

10. The device of claim 9, wherein
the contact area further includes a third sub contact area adjacent to the second sub contact area in the first direction,
the insulating area further includes a second sub insulating area disposed between the second sub contact area and the third sub contact area,
in the area in which the contact area and the one block area overlap,
the third sub contact area includes two terraced portions arranged in the second direction, the two terraced portions belonging to two first conductive layers adjacent in the third direction, and
the second contacts included in the second sub insulating area are electrically coupled to the first contacts included in any one of the second sub contact area and the third sub contact area.

11. The device of claim 5, wherein
an insulating member intersecting one of the subareas among the insulating members is divided at a portion overlapping the insulating area included in the one of the subareas.

12. A semiconductor memory device comprising:
a substrate including a first area, a second area, and a plurality of block areas, the first area and the second area being arranged in a first direction, each of the block areas being provided to extend in the first direction, and the block areas being arranged in a second direction intersecting the first direction;
a plurality of insulating members provided to extend in the first direction, the insulating members being respectively disposed at boundary portions between the block areas;
a plurality of first conductive layers arranged in a third direction intersecting the first and second directions and provided to be separated from one another, the first conductive layers being divided by the insulating members, and the first conductive layers respectively including terraced portions provided not to overlap an upper first conductive layer for each area in which the second area and any one of the block areas overlap;
a plurality of first pillars provided to penetrate the first conductive layers for each area in which the first area and any one of the block areas overlap;
a plurality of first contacts respectively provided on the terraced portions for each of the block areas;
a plurality of second conductive layers respectively coupled to the first contacts above the first conductive layers for each of the block areas; and
a plurality of second contacts provided to extend from a first layer to a second layer and respectively coupled to the second conductive layers for each of the block areas, the first layer being located above the first conductive layers, and the second layer being located between the substrate and the first conductive layers, wherein
the second area includes a plurality of subareas arranged in the second direction, each of the subareas being disposed across a boundary between two different block areas to overlap a part of each of the two different block areas in the second direction, and
each of the subareas includes a first contact area, an insulating area, and a second contact area arranged in the second direction, each of the first contact area and the second contact area including a group of the terraced portions and a group of the first contacts corresponding to one block area, and the insulating area including a group of the second contacts corresponding to two block areas.

13. The device of claim 12, wherein
the subareas include odd-numbered subareas and even-numbered subareas disposed in a zigzag pattern and arranged in the second direction.

14. The device of claim 13, wherein
the odd-numbered subareas are arranged in the second direction,
the even-numbered subareas are arranged in the second direction,
the even-numbered subareas are not included between the odd-numbered subareas in the second direction, and
the odd-numbered subareas are not included between the even-numbered subareas in the second direction.

15. The device of claim 12, wherein
the subareas include a first subarea,
the block areas include a first block area and a second block area that overlap the first subarea and are adjacent to each other in the second direction,
the first contacts included in the first contact area of the first subarea and associated with the first block area and the first contacts included in the second contact area of the first subarea and associated with the second block area are electrically coupled to the second contacts included in the insulating area of the first subarea, respectively.

16. The device of claim 15, wherein
the second conductive layers coupled to the first conductive layers associated with the first block area are arranged in the first direction, and
the second conductive layers coupled to the first conductive layers associated with the second block area are arranged in the first direction.

17. The device of claim 15, wherein
the insulating members include a first insulating member, a second insulating member, and a third insulating member arranged in the second direction, the first block area is disposed between the first insulating member and the second insulating member, and the second block area is disposed between the second insulating member and the third insulating member, and
a distance between the first insulating member and the second insulating member in the second direction is larger at a portion where the second insulating member intersects the first subarea within the second area than within the first area.

18. The device of claim 17, wherein
a distance between the first insulating member and the second insulating member in the second direction is smaller at a portion extending between a second subarea and a third subarea than within the first area, the second subarea and the third subarea being adjacent to the first subarea on both sides of the first subarea within the second area.

19. The device of claim 17, wherein
the first subarea further includes at least one insulator provided to be separated from the insulating members and penetrate the first conductive layers.

20. The device of claim 12, wherein
an insulating member intersecting one of the subareas among the insulating members is divided at a portion overlapping the insulating area included in the one of the subareas.
